(19) United States
(12) Patent Application Publication
(10) Pub. No.: US 2024/0244882 A1
(43) Pub. Date: Jul. 18, 2024

(54) DISPLAY DEVICE AND MANUFACTURING METHOD OF DISPLAY DEVICE

(71) Applicant: SEMICONDUCTOR ENERGY LABORATORY CO., LTD., Atsugi-shi, Kanagawa-ken (JP)

(72) Inventors: Shingo EGUCHI, Atsugi, Kanagawa (JP); Kenichi OKAZAKI, Atsugi, Kanagawa (JP); Yukinori SHIMA, Tatebayashi, Gunma (JP)

(21) Appl. No.: 18/558,233

(22) PCT Filed: Apr. 26, 2022
(86) PCT No.: PCT/IB2022/053835

§ 371 Date: Oct. 31, 2023

(30) Foreign Application Priority Data
May 10, 2021 (JP) 2021-079792

(51) Int. Cl. H10K 59/12; H10K 59/122; H10K 59/35

(52) U.S. Cl. CPC H10K 59/1201; H10K 59/122; H10K 59/35

(57) ABSTRACT

A display device with high resolution is provided. The display device includes a light-emitting element including a first electrode, an organic compound layer, and a second electrode; a first transistor electrically connected to the first electrode; a second transistor electrically connected to a gate of the first transistor; and an insulator provided to cover an end portion of the first electrode. The first transistor contains silicon in a channel formation region. The second transistor includes an oxide semiconductor in a channel formation region. An end portion of the organic compound layer is positioned in the opening portion of the insulator.

### TECHNICAL FIELD

One embodiment of the present invention relates to a display device and a manufacturing method of the display device.

Examples of the technical field of one embodiment of the present invention include, in addition to the above, a semiconductor device, a light-emitting apparatus, an electronic device, an input/output device (e.g., a touch sensor), a driving method thereof, and a manufacturing method thereof.

### BACKGROUND ART

As a manufacturing method of a display device containing organic EL, there is a method in which an EL layer is formed by an inkjet method (see Patent Document 1).

### REFERENCE

### Patent Document

[Patent Document 1] Japanese Published Patent Application No. 2001-185354

### SUMMARY OF THE INVENTION

### Problems to be Solved by the Invention

In Patent Document 1 given above, the nozzle diameter of an inkjet device should fit with the size of an opening portion and therefore the nozzle diameter must be miniaturized for a high-resolution display device. However, the nozzle diameter has a limitation in miniaturization.

In view of the above, an object of one embodiment of the present invention is to increase the resolution of a display device in which at least one organic compound layer is formed by a wet process. An object of one embodiment of the present invention is to provide the display device and a manufacturing method thereof.

Note that the description of these objects does not preclude the existence of other objects. Note that one embodiment of the present invention does not have to achieve all the objects. Note that other objects will be apparent from the description of the specification, the drawings, the claims, and the like, and other objects can be derived from the description of the specification, the drawings, the claims, and the like.

### Means for Solving the Problems

In view of the above problems, one embodiment of the present invention is a display device that includes a light-emitting element including a first electrode, an organic compound layer, and a second electrode: a first transistor electrically connected to the first electrode: a second transistor electrically connected to a gate of the first transistor; and an insulator provided to cover an end portion of the first electrode. The first transistor contains silicon in a channel formation region. The second transistor includes an oxide semiconductor in a channel formation region. An end portion of the organic compound layer is positioned in an opening portion of the insulator.

Another embodiment of the present invention is a display device that includes a light-emitting element including a first electrode, an organic compound layer, and a second electrode: a first transistor electrically connected to the first electrode: a second transistor electrically connected to a gate of the first transistor; and an insulator provided to cover an end portion of the first electrode. The first transistor contains silicon in a channel formation region. The second transistor includes an oxide semiconductor in a channel formation region. An end portion of the organic compound layer does not overlap with a top surface of the insulator.

Another embodiment of the present invention is a display device that includes a light-emitting element including a first electrode, an organic compound layer, and a second electrode: a first transistor electrically connected to the first electrode: a second transistor electrically connected to a gate of the first transistor; and an insulator provided to cover an end portion of the first electrode. The first transistor contains silicon in a channel formation region. The second transistor includes an oxide semiconductor in a channel formation region. An end portion of the organic compound layer is positioned in an opening portion of the insulator. The thickness of the organic compound layer is larger in a neighboring region of the insulator than that in a center region of the opening portion of the insulator.

Another embodiment of the present invention is a display device that includes a light-emitting element including a first electrode, an organic compound layer, and a second electrode: a first transistor electrically connected to the first electrode: a second transistor electrically connected to a gate of the first transistor; and an insulator provided to cover an end portion of the first electrode. The first transistor contains silicon in a channel formation region. The second transistor includes an oxide semiconductor in a channel formation region. An end portion of the organic compound layer does not overlap with a top surface of the insulator. The thickness of the organic compound layer is larger in a neighboring region of the insulator than that in a center region of an opening portion of the insulator.

In any one of the other embodiments of the present invention, the organic compound layer is preferably one or two or more selected from a hole-injection layer, a hole-transport layer, and a light-emitting layer. In any one of the embodiments of the present invention, the organic compound layer is preferably one or both selected from a hole-injection layer and a hole-transport layer.

In any one of the other embodiments of the present invention, the oxide semiconductor preferably contains indium, gallium, and zinc.

In any one of the other embodiments of the present invention, the channel formation region of the first transistor preferably contains polycrystalline silicon.

Another embodiment of the present invention is a manufacturing method of a display device, in which a first transistor containing silicon in a channel formation region and a second transistor including an oxide semiconductor in a channel formation region are formed over a substrate: a first electrode of a first light-emitting element electrically connected to the first transistor is formed: an insulator including a first opening portion and a second opening portion that overlap at least with the first electrode are formed over the first transistor and the second transistor: a first material layer including an organic compound that is included in the first light-emitting element is formed in the first opening portion by a wet process, and a second material layer including an organic compound that is included in a second light-emitting element is formed in the second opening portion by a wet process: a first resist mask and a second resist mask are selectively formed over the first material layer and the second material layer, respectively; and the first material layer is processed using the first resist mask to form a third material layer so as not to overlap with a top surface of the insulator, and the second material layer is processed using the second resist mask to form a fourth material layer so as not to overlap with a top surface of the insulator.

Another embodiment of the present invention is a manufacturing method of a display device, in which a first transistor containing silicon in a channel formation region and a second transistor including an oxide semiconductor in a channel formation region are formed over a substrate: a first electrode of a first light-emitting element electrically connected to the first transistor is formed: an insulator including a first opening portion and a second opening portion that overlap at least with the first electrode are formed over the first transistor and the second transistor; a first material layer containing a light-emitting material that is included in the first light-emitting element is formed in the first opening portion by a wet process, and a second material layer containing a light-emitting material that is included in a second light-emitting element is formed in the second opening portion by a wet process: a first resist mask and a second resist mask are selectively formed over the first material layer and the second material layer, respectively; and the first material layer is processed using the first resist mask to form a third material layer so as not to overlap with a top surface of the insulator, and the second material layer is processed using the second resist mask to form a fourth material layer so as not to overlap with a top surface of the insulator.

In any one of the other embodiments of the present invention, an inkjet method or a spin coating method is preferably used as the wet process.

In any one of the other embodiments of the present invention, a sacrificial layer is preferably formed below the first resist mask and the second resist mask.

### Effect of the Invention

According to one embodiment of the present invention, a high-resolution display device and a manufacturing method thereof can be provided. According to one embodiment of the present invention, the display device can be manufactured by a wet process, and thus, the cost can be reduced.

Note that the description of these effects does not preclude the existence of other effects. Note that one embodiment of the present invention does not need to have all the effects. Note that other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A to FIG. 1E are diagrams illustrating a manufacturing method of a display device of an embodiment.

FIG. 2A to FIG. 2E are diagrams illustrating a manufacturing method of a display device of an embodiment.

FIG. 3A to FIG. 3F are diagrams each illustrating a light-emitting element of an embodiment.

FIG. 4A to FIG. 4E are diagrams illustrating a manufacturing method of a display device of an embodiment.

FIG. 5 is a flow chart showing a manufacturing method of a display device of an embodiment.

FIG. 6A is a diagram illustrating a structure example of a display device. FIG. 6B to FIG. 6D are diagrams illustrating structure examples of a pixel circuit.

FIG. 7A to FIG. 7D are diagrams illustrating cross sections of transistors.

FIG. 8A to FIG. 8E are diagrams illustrating structures of a data processing device of an embodiment.

FIG. 9A to FIG. 9E are diagrams illustrating structures of a data processing device of an embodiment.

FIG. 10A and FIG. 10B are diagrams illustrating structures of a data processing device of an embodiment.

### MODE FOR CARRYING OUT THE INVENTION

Embodiments will be described below with reference to the drawings. Note that the embodiments can be implemented in many different modes, and it is readily understood by those skilled in the art that modes and details thereof can be changed in various ways without departing from the spirit and scope thereof. Therefore, the present invention should not be construed as being limited to the description of embodiments and the like below.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

Note that in this specification and the like, ordinal numbers such as “first,” “second,” and the like are used in order to avoid confusion among components and do not limit the number.

In the case where the expression “B over A” or “B under A” is used in this specification and the like, for example, A and B do not always need to include a region where they are in contact with each other.

In this specification and the like, the term “film” and the term “layer” can be interchanged with each other. For example, in some cases, the term “conductive layer” and the term “insulating layer” can be interchanged with the term “conductive film” and the term “insulating film”, respectively.

In this specification and the like, a display panel that is one embodiment of a display device has a function of displaying (outputting) an image or the like on (to) a display surface. Therefore, the display panel is one embodiment of an output device.

In this specification and the like, a substrate of a display panel to which a connector such as an FPC (Flexible Printed Circuit) or a TCP (Tape Carrier Package) is attached, or a substrate on which an IC is mounted by a COG (Chip On Glass) method or the like is referred to as a display panel module or a display module in some cases. The display panel module or the display module is one embodiment of a display device.

In this specification and the like, the terms “source” and “drain” of a transistor interchange with each other depending on the polarity of the transistor or the levels of potentials applied to the terminals. In general, in an n-channel transistor, a terminal to which a lower potential is applied is called a source, and a terminal to which a higher potential is applied is called a drain. In a p-channel transistor, a terminal to which a lower potential is applied is called a drain, and a terminal to which a higher potential is applied is called a source. In this specification and the like, for the sake of convenience, the connection relationship of a transistor is sometimes described assuming that the source and the drain are fixed: in reality, the names of the source and the drain interchange with each other according to the above relationship of the potentials.

In this specification and the like, the terms “first electrode” and “second electrode” are sometimes used in description of a source and a drain of a transistor.

In this specification and the like, a “source” of a transistor means a source region that is part of a semiconductor layer functioning as an active layer or means a source electrode connected to the semiconductor layer. Similarly, a drain of a transistor means a drain region that is part of the above semiconductor layer or a drain electrode connected to the above semiconductor layer. Moreover, a gate of a transistor means a gate electrode.

In this specification and the like, a state in which transistors are connected in series means, for example, a state in which only one of a source and a drain of a first transistor is connected to only one of a source and a drain of a second transistor. In addition, a state in which transistors are connected in parallel means a state in which one of a source and a drain of a first transistor is connected to one of a source and a drain of a second transistor and the other of the source and the drain of the first transistor is connected to the other of the source and the drain of the second transistor.

In this specification and the like, connection is sometimes referred to as electrical connection and may refer to a state where a current, a voltage, or a potential can be supplied or transmitted. Accordingly, connection may refer to connection via an element such as a wiring, a resistor, a diode, or a transistor. Electrical connection may refer to direct connection without via an element such as a wiring, a resistor, a diode, or a transistor.

In this specification and the like, a conductive layer sometimes has a plurality of functions such as those of a wiring and an electrode. In this specification and the like, the phrase “a wiring is connected to an electrode” may be used also in the case where one conductive layer has the above two functions.

In this specification and the like, a device in which a light-emitting layer is formed using a metal mask (MM) is sometimes referred to as a light-emitting device having a metal mask (MM) structure. A metal mask may be referred to as a fine metal mask (FMM) depending on the minuteness of its opening portions. In this specification and the like, a device including a light-emitting layer formed without using a metal mask or a fine metal mask is sometimes referred to as a light-emitting device having a metal maskless (MML) structure.

In this specification and the like, a light-emitting element includes a pair of electrodes and is a stack in which an organic compound layer is sandwiched between the pair of electrodes, and the light-emitting element is sometimes referred to as a light-emitting device. The organic compound layer is a stack including at least a light-emitting layer, and the light-emitting layer and the like is sometimes referred to as a functional layer. In the functional layer, a hole-injection layer, a hole-transport layer, an electron-transport layer, or an electron-injection layer is included in addition to the light-emitting layer. The pair of electrode function as an anode and a cathode.

In this specification and the like, a structure in which light-emitting layers of light-emitting elements for multiple colors (e.g., red (R), green (G), and blue (B)) are separately formed is sometimes referred to as an SBS (Side By Side) structure. In this specification and the like, a light-emitting element capable of emitting white light may be referred to as a white-light-emitting element. Note that a combination of white-light-emitting elements with coloring layers (e.g., color filters) enables a full-color display device. Note that color filters can be used as the coloring layers, for example.

The light-emitting elements can be roughly classified into a single structure and a tandem structure. In the single structure, one light-emitting unit is provided between a pair of electrodes. The light-emitting unit is a stack not including an electrode but including one or more light-emitting layers. To obtain white light emission with the single structure, one light-emitting unit includes two or more light-emitting layers, and the light-emitting layers have complementary emission colors. For example, when emission color of a first light-emitting layer and emission color of a second light-emitting layer are complementary colors, the light-emitting element can be configured to emit white light as a whole. A light-emitting element including three or more light-emitting layers can also emit white light when the light-emitting layers emit light of complementary colors.

A device having a tandem structure includes two or more light-emitting units between a pair of electrodes, and each light-emitting unit preferably includes one or more light-emitting layers. In the tandem structure, an intermediate layer such as a charge-generation layer is suitably provided between the plurality of light-emitting units. To obtain white light emission with a tandem structure, the light-emitting element is configured to obtain white light emission by combining light from light-emitting layers of two or more light-emitting units. In the structure capable of white light emission, light of complementary colors is emitted as in the single structure.

When the above-described white-light-emitting element (the single structure or the tandem structure) and a light-emitting element having an SBS structure are compared, the light-emitting element having an SBS structure consumes lower power than the white-light-emitting element. To reduce power consumption, the light-emitting element having an SBS structure is suitably used. By contrast, the white-light-emitting element is suitable in terms of lower manufacturing cost or higher manufacturing yield because the manufacturing process of the white-light-emitting element is simpler than that of the light-emitting element having an SBS structure.

### Embodiment 1

In this embodiment, a display device of one embodiment of the present invention and a manufacturing method (referred to as Manufacturing Method 1) thereof will be described.

A manufacturing method of the display device in one embodiment of the present invention includes a step in which an organic compound layer included in a light-emitting element is formed by a wet process. As the organic compound layer included in the light-emitting element, a layer containing a hole-injection material, a hole-transport material, a light-emitting material, an electron-transport material, or an electron-injection material is given. The layer is referred to as a hole-injection layer, a hole-transport layer, a light-emitting layer, an electron-transport layer, or an electron-injection layer. The hole-injection layer is referred to as an HIL that is an abbreviation of Hole Injection Layer in some cases. The hole-transport layer is referred to as an HTL that is an abbreviation of Hole Transport Layer in some cases. The electron-injection layer is referred to as an EIL that is an abbreviation of Electron Injection Layer in some cases. The electron-transport layer is referred to as an ETL that is an abbreviation of Electron Transport Layer in some cases. Detailed description on the layers will be made later.

A wet process is the method in which a liquid composition is obtained by a process of dissolution or dispersion of a material having a predetermined function into a solvent for liquefaction and the liquid composition is applied. Examples of the material having a predetermined function include a material having a hole-injection property, a material having a hole-transport property, a light-emitting material, a material having an electron-transport property, and a material having an electron-injection property. The liquid composition is referred to as a droplet or an ink material in some cases. After being applied, the liquid composition is solidified or made to be a thin film through a drying step or a curing step, whereby the organic compound layer including the above layers can be obtained.

A wet process includes an inkjet method, a spin coating method, a coating method, a nozzle printing method, gravure printing, or the like, and the details are described later. A wet process generates fewer waste materials than an evaporation method, and thus the cost can be reduced.

### <Manufacturing Method 1 of Display Device>

In Manufacturing Method 1 of a display device described in this embodiment, one or two or more of a hole-injection layer, a hole-transport layer, and a light-emitting layer are used as an organic compound layer formed by a wet process, and an inkjet method is used as the wet process. In order to form the one or two or more of a hole-injection layer, a hole-transport layer, and a light-emitting layer by an inkjet method, it is preferable that droplets respectively contain a solvent and a hole-injection material, a solvent and a hole-transport material, and a solvent and a light-emitting material. Note that the solvent is unnecessary in some materials. An inkjet device for achieving the inkjet method is described later.

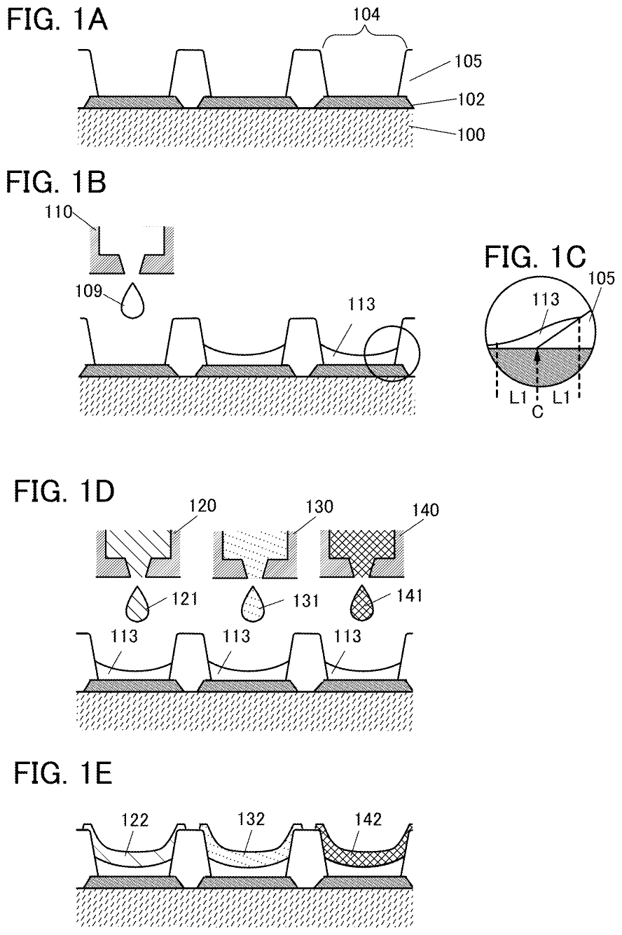

FIG. 1A illustrates a first substrate 100, a first electrode 102 provided over the first substrate 100, and an insulator 105 that covers at least an end portion of the first electrode 102 and includes a region overlapping with the first electrode 102 in a top view, i.e., includes an opening portion 104 exposing the first electrode 102, which are included in a display device. A semiconductor element and the like is provided over the first substrate 100. Note that a material and the like used in the first substrate 100 are described later.

A transistor is often used as the semiconductor element, and the first substrate 100 is referred to as a transistor substrate in some cases. A transistor or the like can function as a switching element or the like, and the switching element can change whether the state of a light-emitting element is light emission or non-light emission. The transistor changing the state of light emission or non-light emission is referred to as a driving transistor in some cases. A pixel circuit is provided with a selection transistor other than the driving transistor in some cases, and the selection transistor is controlled by a gate signal, for example. When the pixel circuit includes a plurality of transistors, ordinal numbers are used in order to distinguish the transistors: for example, a first transistor and a second transistor.

A display device in which the semiconductor element is provided for each light-emitting element is referred to as an active matrix display device in some cases. A display device in which the semiconductor element is commonly provided for a plurality of light-emitting elements is referred to as a passive matrix display device in some cases. The manufacturing method of a display device of one embodiment of the present invention can be used for an active matrix display device and a passive matrix display device.

The first electrode 102 illustrated in FIG. 1A corresponds to any one of a pair of electrodes included in the light-emitting element and has a function of a cathode or an anode in accordance with a light-emitting element. Therefore, a conductive material used in the first electrode 102 is preferably selected in consideration of a work function according to the cathode or the anode. The conductive material and the like that can be used in the first electrode 102 is described later.

When the first electrode 102 contains a light-transmitting conductive material, a display device with a so-called bottom-emission structure in which light of the light-emitting element is emitted downward below the first electrode 102, i.e., to the first substrate 100 side can be provided. A light-transmitting property means transmitting visible light. When the first electrode 102 includes a reflective conductive material, a display device with a so-called top-emission structure in which light of the light-emitting element is emitted upward over the first electrode 102 can be provided. A reflective property means reflecting visible light. The manufacturing method of the display device of one embodiment of the present invention can be used for a bottom-emission display device and a top-emission display device.

As illustrated in FIG. 1A, the end portion of the first electrode 102 is preferably tilted with respect to the formation surface: however, since the end portion of the first electrode 102 is covered with the insulator 105, the end portion of the first electrode 102 may be perpendicular to or substantially perpendicular to the formation surface. The state where the end portion is tilted is referred to as a taper in some cases. When the first electrode 102 has a stacked-layer structure of a conductive material and the like, an end portion of a lower layer may be tilted, and an end portion of an upper layer may be perpendicular or substantially perpendicular. Alternatively, when the first electrode 102 has a stacked-layer structure of a conductive material and the like, an end portion of a lower layer may be perpendicular or substantially perpendicular, and an end portion of an upper layer may be tilted.

The insulator 105 is located at the interface between adjacent light-emitting elements, i.e., located between the adjacent light-emitting elements and referred to as a partition, a bank, or an embankment in some cases. The adjacent light-emitting elements mean light-emitting elements next to each other, and the light-emitting elements are not necessarily in direct contact with each other. The light-emitting elements next to each other are placed such that at least bottom electrodes include a space as illustrated in FIG. 1A, the light-emitting elements are sectioned as one light-emitting element by the insulator 105, and one independent light-emitting element can be determined. Although the insulator 105 looks divided in FIG. 1A which is a cross-sectional view; the insulator 105 has a continuous structure when seen in a top view and includes a selective opening portion. That is, the insulator 105 includes the opening portion 104 exposing the first electrode 102. The opening portion 104 can be formed by a photolithography method, for example. As a photolithography method, there are a method in which a resist mask is formed over a thin film to be processed, the thin film is processed by etching or the like, and the resist mask is removed, and a method in which a photosensitive thin film is formed, and then exposed to light and developed to be processed into a desired shape. A material and the like used in the insulator 105 is described later.

FIG. 1B illustrates the state where, over the first electrode 102, a droplet containing a hole-injection material is dripped by an inkjet method, a droplet containing a hole-transport material is dripped by an inkjet method, or a droplet containing a hole-injection material and a droplet containing a hole-transport material are sequentially dripped by an inkjet method. A droplet 109 is dripped from a nozzle 110 to the opening portion 104 provided over the first substrate 100, and the droplet 109 contains a hole-transport material or a hole-injection material. The nozzle 110 included in an inkjet device and the first substrate 100 are relatively moved when dripping the droplet 109, whereby a linear hole-injection layer, a linear hole-transport layer, or a linear hole-transport layer stacked over a linear hole-injection layer can be formed. Depending on the amount of the droplet, the layer is not formed to be linear but divided by the insulator 105; therefore, an island-shaped hole-injection layer, an island-shaped hole-transport layer, or an island-shaped hole-transport layer stacked over an island-shaped hole-injection layer can be formed. It can be said that as illustrated in FIG. 1B, an end portion of the island-shaped hole-injection layer and an end portion of the island-shaped hole-transport layer are positioned in the opening portion of the insulator. “The end portion of the hole-injection layer and the end portion of the hole-transport layer are positioned in the opening portion of the insulator” can be expressed as “the end portions do not overlap with a top surface of the insulator” as illustrated in FIG. 1B. In the case of stacking the layers, the island-shaped hole-transport layer can be formed over the linear hole-injection layer, or the linear hole-transport layer can be formed over the island-shaped hole-injection layer.

As already described above, the hole-injection layer can be formed with the droplet containing a hole-injection material. Furthermore, the hole-injection layer can be formed with the droplet containing a hole-transport material. Accordingly, the hole-injection layer can be formed by a wet process, and the hole-transport layer can be formed by a process other than a wet process. The hole-injection layer may be formed by a process other than a wet process, and the hole-transport layer may be formed by a wet process. Moreover, both the hole-injection layer and the hole-transport layer can be formed by a wet process. Needless to say, both the hole-injection layer and the hole-transport layer can be formed by a process other than a wet process.

The droplet 109 dripped into the opening portion 104 first becomes a material layer 113. FIG. 1B illustrates the state where an end portion of the material layer 113 is positioned in the opening portion of the insulator 105. The material layer 113 includes a hole-injection layer in which a solvent or the like is removed from the droplet 109. Alternatively, the material layer 113 includes a hole-transport layer in which a solvent or the like is removed from the droplet 109. Further alternatively, the material layer 113 includes the hole-injection layer and the hole-transport layer thereover.

The solvent or the like is preferably removed from the droplet 109 through a drying step, for example. Heat may be added in the drying step. Furthermore, the material layer 113 is preferably subjected to a curing step. The curing step includes one or both selected from a light irradiation step and a heating step. As a light source of the light irradiation, an ultraviolet ray or an infrared ray is preferably used.

In the case where both the hole-injection layer and the hole-transport layer are formed by a wet process, it is preferable that dripping for the hole-transport layer be started after one or both of steps selected from a drying step and a curing step for the hole-injection layer. Through such steps, the end portion of the hole-injection layer is not aligned with but deviates from the end portion of the hole-transport layer.

One or both selected from the hole-transport layer and the hole-injection layer can be shared with the light-emitting elements. Being shared means that the light-emitting elements can use one or both selected from the hole-transport layer and the hole-injection layer in common. The light-emitting elements include light-emitting elements exhibiting different emission colors or light-emitting elements exhibiting the same emission color.

The material layer 113 has a layered form in many cases, and thus the shared material layer is sometimes referred to as a common layer. Furthermore, when one or both selected from the hole-transport layer and the hole-injection layer are common layers, they are sometimes referred to as lower common layers of the light-emitting elements.

The common layers may be each independent between the light-emitting elements or may be continuous in the light-emitting elements across the insulator 105. In view of the above, the droplet 109 for the common layer is not necessarily dripped in the opening portion 104 selectively, and can be continuously dripped in a plurality of opening portions 104. In an inkjet device used for continuous dripping in the plurality of opening portions 104, a plurality of nozzles 110 are preferably provided, in which case the productivity increases. The productivity increases also when the diameter of the nozzle 110 is larger than the width of the opening portion 104. The droplet 109 may be continuously dripped to be linear.

A method other than an inkjet method can be used as a formation method of the common layer, and for example, a spin coating method may be used. With the spin coating method, the droplet 109 can coat the entire formation surface including the opening portion 104.

An evaporation method may be used as a formation method of the common layer. As an evaporation method, a vacuum evaporation method is preferable. With the evaporation method, an evaporation material can be deposited to the entire formation surface including the opening portion 104.

The hole-injection layer and the hole-transport layer can be the common layers, and they are selectively formed in the opening portion 104 and are not necessarily formed on a top surface of the insulator 105. Therefore, the volume of the droplet 109 for forming the layers may be small with respect to the capacity of the opening portion 104. According to the condition, the droplet 109 is dripped in the opening portion 104, not on the top surface of the insulator 105, and by performing surface treatment on the insulator 105, the droplet 109 can be selectively dripped in the opening portion 104. The surface treatment includes treatment making the surface of the insulator 105 hydrophilic or water-repellent with respect to the solvent of the droplet 109.

A side surface of the insulator 105 is tilted in the opening portion 104 in some cases. The state where the side surface is tilted is referred to as a taper in some cases. The insulator 105 with the tilted side surface may be subjected to the surface treatment. Note that without the surface treatment, the droplet 109 can be dripped in the opening portion 104 utilizing the tilt.

The thickness of the material layer 113 formed by a wet process is described with reference to FIG. 1C which shows a region denoted by a circle in FIG. 1B, that is, an enlarged view of an end portion of the insulator 105. First, a lower end portion of the insulator 105 is regarded as a center (C). A distance L1 is from the center (C) to an end of the material layer 113 (an end overlapping with the tilt of the insulator 105). Similarly, the distance L1 is set on a side opposite to the end of the material layer 113 from the center (C), and an area from the center (C) to the distance L1 is shown. An area within the distance L1 including the end portion of the insulator 105 is referred to as a neighboring region of the insulator 105. In the neighboring region of the insulator 105, the thickness of the material layer 113 increases. The material layer 113 has the largest thickness in a region overlapping with the center (C) in many cases. Accordingly, the thickness of the material layer 113 is larger in the neighboring region of the insulator 105 than that in a region including a center of the opening portion 104 (a center region of the opening portion). The material layer 113 having an increased thickness in the neighboring region of the insulator 105 is regarded as being formed by a wet process.

FIG. 1D illustrates the state where organic compound materials containing light-emitting materials of the light-emitting elements are dripped by a wet process, typically an inkjet method. In the case where the light-emitting materials correspond to red, green, and blue, a nozzle 120, a nozzle 130, and a nozzle 140 are prepared. When droplets containing the light-emitting materials are dripped, the material layer 113 is formed on a surface where each of the droplets is dripped, and the first substrate 100 and the nozzle 120, the nozzle 130, and the nozzle 140 are relatively moved. The droplets dripped from the nozzles are a droplet 121, a droplet 131, and a droplet 141. The droplets contain a red-light-emitting material, a green-light-emitting material, and a blue-light-emitting material.

Light-emitting layers containing the light-emitting materials are each thicker than one or both selected from the hole-transport layer and the hole-injection layer in many cases. Therefore, the dripping amount of each of the droplet 121, the droplet 131, and the droplet 141 is larger than that of the droplet 109. The droplet 121, the droplet 131, and the droplet 141 are each dripped in the opening portion 104 and outside the opening portion 104 in some cases. That is, the droplet 121, the droplet 131, and the droplet 141 are each dripped on the top surface of the insulator 105 in some cases. Note that the droplet 121, the droplet 131, and the droplet 141 are each dripped in the opening portion 104 and are not necessarily dripped on the top surface of the insulator 105.

Therefore, as illustrated in FIG. 1E, a material layer 122, a material layer 132, and a material layer 142 corresponding to the droplet 121, the droplet 131, and the droplet 141 are each formed also on the top surface of the insulator 105. The material layer 122, the material layer 132, and the material layer 142 are sometimes referred to as a first material layer, a second material layer, and a third material layer to be distinguished from each other. Furthermore, the material layer 122, the material layer 132, and the material layer 142 are collectively referred to as material layers in some cases. The light-emitting layers each of which is one of the material layers include layers containing the light-emitting materials in which solvents or the like are removed from the droplets. The light-emitting layers include a layer containing the red-light-emitting material (sometimes referred to as a red-light-emitting layer), a layer containing the green-light-emitting material (sometimes referred to as a green-light-emitting layer), and a layer containing the blue-light-emitting material (sometimes referred to as a blue-light-emitting layer).

The solvent or the like is preferably removed from the droplet through a drying step, for example. Heat may be added in the drying step. Furthermore, the material layer 113 is preferably subjected to a curing step. The curing step includes one or both selected from a light irradiation step and a heating step. As a light source of the light irradiation, an ultraviolet ray or an infrared ray is preferably used.

The thickness of each of the light-emitting layers is smaller in a region overlapping with the top surface of the insulator 105 than that in a region overlapping with the opening portion 104.

Similar to the material layer 113, the thickness of each of the light-emitting layers is increased in the neighboring region of the insulator 105. That is, the thickness of each of the material layers is larger in the neighboring region of the insulator 105 than that in the center region of the opening portion in the insulator. The light-emitting layers each having an increased thickness in the neighboring region of the insulator are regarded as being formed by a wet process.

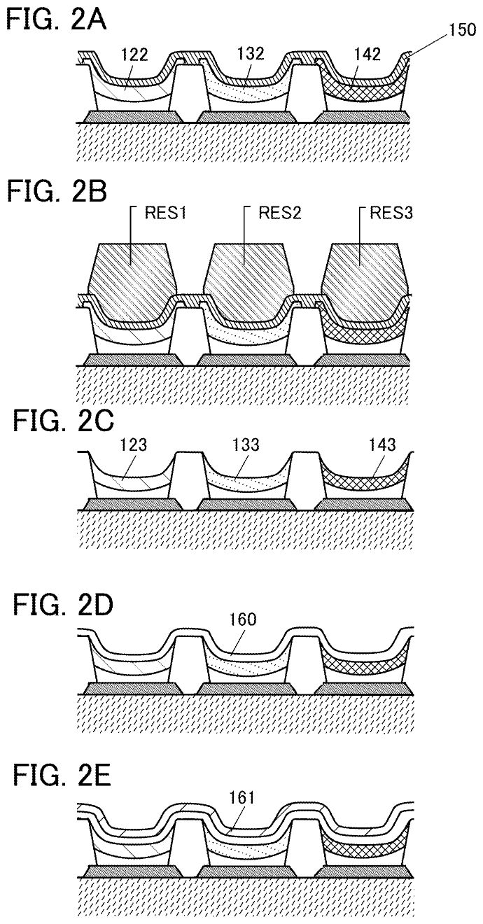

As illustrated in FIG. 2A, a sacrificial layer 150 is formed over the material layer 122, the material layer 132, and the material layer 142. The sacrificial layer is provided for protecting the material layers (each of the material layers is a target of processing and sometimes referred to as a layer to be processed) formed below the sacrificial layer from process damage when the material layers are processed by etching or the like. Thus, the sacrificial layer 150 may be formed to have a larger thickness than the light-emitting layers. A material and the like used in the sacrificial layer 150 is described later.

As illustrated in FIG. 2B, a first resist mask RES1, a second resist mask RES2, and a third resist mask RES3 are formed to overlap with the light-emitting layers. The first resist mask RES1, the second resist mask RES2, and the third resist mask RES3 are each preferably formed to overlap with the first electrode 102. According to the cross-sectional view in FIG. 2B, the width of the first resist mask RES1 is less than or equal to the width of the opening portion 104. The width of the second resist mask RES2 and the width of the third resist mask RES3 are preferably similar to the width of the first resist mask RES1. As each of the first resist mask RES1, the second resist mask RES2, and the third resist mask RES3, a negative-type resist or a positive-type resist can be used.

With the use of the first resist mask RES1, the material layer 122 is processed, or more specifically is partly removed, thereby forming a processed material layer 123 as illustrated in FIG. 2C. With the use of the second resist mask RES2, the material layer 132 is processed, or more specifically is partly removed, thereby forming a processed material layer 133. With the use of the third resist mask RES3, the material layer 142 is processed, or more specifically is partly removed, thereby forming a processed material layer 143. In the processing step, a photolithography method can be used, for example. As a photolithography method, there is a method in which a resist mask is formed over a thin film to be processed, the thin film is processed by etching or the like, and the resist mask is removed.

As illustrated in FIG. 2C, the sacrificial layer 150 is removed at the same time as the first resist mask RES1, the second resist mask RES2, and the third resist mask RES3, and the processed material layer 123, the processed material layer 133, and the processed material layer 143 can be obtained. It is preferable that an end portion of each of the processed material layer 123, the processed material layer 133, and the processed material layer 143 does not overlap with the top surface of the insulator 105 and the end portion of each of the processed material layers be positioned in the opening portion 104. Note that in order to inhibit occurrence of crosstalk, the processed material layer 123, the processed material layer 133, and the processed material layer 143 are at least divided from each other, and the end portion of each of the processed material layers may be positioned in the region overlapping with the top surface of the insulator 105.

Furthermore, in order to inhibit occurrence of crosstalk, part of the material layers is insulated to electrically divide the material layers. By irradiating the material layers in the region overlapping with the top surface of the insulator 105 with a laser, part of the material layers can be insulated.

Since the processing step is performed in the state where the sacrificial layer 150 is provided, the material layers are not damaged during the step, which is preferable.

In the processing step, an etching method, a laser ablation method, or the like can be used. Dry etching or wet etching can be used as the etching. In a laser ablation method, laser irradiation may be performed after providing a light-absorbing layer or a light-reflecting layer.

Through the processing step, a minute light-emitting element can be provided regardless of the nozzle diameter. In this manner, a high-resolution display device can be provided. Through more processing step, the material layers, typically the light-emitting layers are divided in adjacent light-emitting elements, and thus a display device with less crosstalk can be provided.

Although the adjacent light-emitting elements preferably exhibit different emission colors, the adjacent light-emitting elements may exhibit the same emission color. For example, the material layer 123 can be for a red light-emitting element, the material layer 133 can be for a green light-emitting element, and the material layer 143 can be for a blue light-emitting element. Such a structure in which light-emitting layers are separately patterned is referred to as an SBS structure in some cases. Although the structure having three colors is described as an example, one embodiment of the present invention is not limited thereto. For example, the structure may have four or more colors.

The manufacturing method of the display device of one embodiment of the present invention includes a step forming an organic compound layer, i.e., a functional layer not using a metal mask but by a method including a wet process or the like, and a step, after the formation, processing the organic compound layer. Through the steps, a high-resolution display device or a display device having a high aperture ratio, which has been difficult to achieve, can be obtained. Since the organic compound layer can be independent through the processing step, occurrence of crosstalk can be inhibited.

Furthermore, since the organic compound layer includes a light-emitting layer, the light-emitting layer can be separately patterned in each light-emitting element. A display device including the separately patterned light-emitting layer can perform clear display with high contrast.

In the processing step, a sacrificial layer can be provided over a layer to be processed, and process damage on the layer to be processed can be reduced: whereby, the reliability of the display device can be increased.

As illustrated in FIG. 2D, one or more layers 160 selected from a layer containing an electron-transport material and a layer containing an electron-injection material are formed. The layer containing an electron-transport material is sometimes referred to as an electron-transport layer. The layer containing an electron-injection material is sometimes referred to as an electron-injection layer. One or both of the electron-transport layer and the electron-injection layer may be common layers: when one or both of the electron-transport layer and the electron-injection layer are common layers, they are referred to as upper common layers of the light-emitting elements in some cases.

A method other than an inkjet method can be used as a formation method of the common layer, and for example, a spin coating method may be used.

An evaporation method may be used as a formation method of the common layer. As an evaporation method, a vacuum evaporation method is preferable.

As illustrated in FIG. 2E, a second electrode 161 is formed by an evaporation method, a sputtering method, or a CVD method. As an evaporation method, a vacuum evaporation method is preferable. The second electrode 161 is a common layer and functions as an electrode, and thus referred to as a common electrode in some cases.

A protective film may be formed over the second electrode 161.

In the manufacturing method of one embodiment of the present invention, the material layers containing the light-emitting materials are processed to be separated by patterning using a photolithography method. The patterning using a photolithography method is preferably performed once, not a plurality of times, on each light-emitting element. Although material layers formed by a wet process are difficult to be separately patterned with high resolution because of the limitation of the nozzle diameter or the like, patterning using a photolithography method makes high-resolution processing possible. Therefore, a high-resolution light-emitting device (display device) can be manufactured.

The material layers containing the light-emitting materials sometimes cause crosstalk due to the conductivity. Therefore, high-resolution processing by patterning using a photolithography method as described in the manufacturing method of one embodiment of the present invention can inhibit occurrence of crosstalk between adjacent light-emitting devices. As each of the material layer, a charge-generation layer may be processed by a photolithography method. An end portion (side surface) of the material layers that contain the light-emitting materials and are processed by patterning using a photolithography method each have a steep with respect to the formation surface, which is suitable for inhibiting occurrence of crosstalk.

Materials and the like that can be used for the components are described.

### <Material of First Substrate>

For the first substrate 100, a material such as glass, quartz, ceramic, sapphire, or an organic resin can be used. Since the above material has a light-transmitting property, light from the light-emitting element can be extracted through the first substrate 100. Despite the name, “substrate” can have flexibility with the use of an organic resin given as the above material. Furthermore, the thickness can be smaller than that of the image of “substrate,” and a film form can be obtained. Thus, the first substrate 100 can have flexibility and a film form depending on the material used for the first substrate 100. Other than the above materials, a metal substrate or the like using a metal material or an alloy material can be used. Such a material has no light-transmitting property and therefore can be used when light of the light-emitting element is not extracted through the first substrate 100.

### <Material of First Electrode>

When the first electrode 102 is used as the cathode, a metal, an alloy, an electrically conductive compound, or a mixture thereof having a low work function (specifically, 3.8 eV or less) or the like can be used. Specific examples of the cathode material include elements belonging to Groups 1 and 2 of the periodic table, such as alkali metals (e.g., lithium (Li) and cesium (Cs)), alkaline earth metals such as magnesium (Mg), calcium (Ca), and strontium (Sr), alloys containing these elements (e.g., MgAg and AlLi), rare earth metals such as europium (Eu) and ytterbium (Yb), and alloys containing these rare earth metals. However, when an electron-injection layer is provided between the cathode and the electron-transport layer, any of a variety of conductive materials such as Al, Ag, ITO, or indium oxide-tin oxide containing silicon or silicon oxide can be used for the cathode regardless of the work function. Films of these conductive materials can be formed by a sputtering method, an inkjet method, a spin coating method, or the like.

When the first electrode 102 is used as the anode, a metal, an alloy, or a conductive compound having a high work function (specifically, 4.0 eV or more), a mixture thereof, or the like is preferably used. Specifically, for example, indium oxide-tin oxide (ITO: Indium Tin Oxide), indium oxide-tin oxide containing silicon or silicon oxide, indium oxide-zinc oxide (IZO: Indium Zinc Oxide), and indium oxide containing tungsten oxide and zinc oxide (IWZO) can be given. These conductive metal oxide films are usually deposited by a sputtering method but may also be formed by application of a sol-gel method or the like. For example, indium oxide-zinc oxide can be formed by a sputtering method using a target in which, to indium oxide, zinc oxide is added at greater than or equal to 1 wt % and less than or equal to 20 wt %. Furthermore, indium oxide containing tungsten oxide and zinc oxide (IWZO) can be deposited by a sputtering method using a target in which, to indium oxide, tungsten oxide is added at greater than or equal to 0.5 wt % and less than or equal to 5 wt % and zinc oxide is added at greater than or equal to 0.1 wt % and less than or equal to 1 wt %. In addition, gold (Au), platinum (Pt), nickel (Ni), tungsten (W), chromium (Cr), molybdenum (Mo), iron (Fe), cobalt (Co), copper (Cu), palladium (Pd), a nitride of a metal (such as titanium nitride), and the like can be given. By forming the above-mentioned composite material so as to be in contact with the anode, a material for the anode can be selected regardless the magnitude of its work function.

### <Material of Insulator>

An organic material or an inorganic material can be used for the insulator. For example, the insulator preferably includes an organic resin such as a polyimide resin, a polyamide resin, an acrylic resin, a siloxane resin, a silicone resin, an epoxy resin, or a phenol resin. The insulator preferably includes one or more of aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, and tantalum oxide as the other examples. Alternatively, a stack of the above materials may be used. Note that a material obtained by adding an impurity element, such as lanthanum (La), nitrogen, or zirconium (Zr), to the above material may be used.

An upper end portion and a lower end portion of the insulator 105 preferably have curvature. The insulator 105 can have the above curved surface by using a positive-type photosensitive acrylic resin. A negative-type photosensitive resin or a positive-type photosensitive resin can be used for the insulator 105.

### <Sacrificial Layer>

As the sacrificial layer 150, it is possible to use a film highly resistant to etching treatment performed on the material layer 122, the material layer 132, and the material layer 142, i.e., a film having high etching selectivity. The sacrificial layer 150 preferably has a stacked-layer structure of a first sacrificial layer and a second sacrificial layer which have different etching selectivities. Moreover, for the sacrificial layer 150, it is possible to use a film that can be removed by a wet etching method less likely to cause damage to the material layers.

The sacrificial layer 150 can be formed using an inorganic film such as a metal film, an alloy film, a metal oxide film, a semiconductor film, or an inorganic insulating film, for example. The sacrificial layer 150 can be formed by any of a variety of film formation methods such as a sputtering method, an evaporation method, a CVD method, and an ALD method.

For the sacrificial layer 150, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used. It is particularly preferable to use a low-melting-point material such as aluminum or silver.

The sacrificial layer 150 can be formed using a metal oxide such as indium gallium zinc oxide (In—Ga—Zn oxide, also referred to as IGZO). It is also possible to use indium oxide, an indium zinc oxide (an In—Zn oxide), an indium tin oxide (an In—Sn oxide), an indium titanium oxide (an In—Ti oxide), an indium tin zinc oxide (an In—Sn—Zn oxide), an indium titanium zinc oxide (an In—Ti—Zn oxide), an indium gallium tin zinc oxide (an In—Ga—Sn—Zn oxide), or the like. Alternatively, indium tin oxide containing silicon can also be used, for example.

Note that an element M (M is one or more kinds selected from aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used instead of gallium. Specifically, M is preferably one or more kinds selected from gallium, aluminum, and yttrium.

For the sacrificial layer 150, an inorganic insulating material such as aluminum oxide, hafnium oxide, or silicon oxide can be used.

The sacrificial layer 150 is preferably formed using material that can be dissolved in a solvent chemically stable with respect to at least the uppermost films of the material layers, i.e., the films positioned on the formation surface of the sacrificial layer 150. Specifically, a material that will be dissolved in water or alcohol can be suitably used for the sacrificial layer 150. In formation of the sacrificial layer 150, it is preferable that application of such a material dissolved in a solvent such as water or alcohol be performed by a wet film formation method and followed by heat treatment for evaporating the solvent. In that case, the heat treatment is preferably performed in a reduced-pressure atmosphere, in which case the solvent can be removed at a low temperature in a short time, so that thermal damage to the material layers can be reduced.

In the case where the sacrificial layer 150 having a stacked-layer structure is formed, the stacked-layer structure can include the first sacrificial layer formed using any of the above-described materials and the second sacrificial layer thereover.

The second sacrificial layer in that case is a film used as a hard mask for etching of the first sacrificial layer. In processing the second sacrificial layer, the first sacrificial layer is exposed. Thus, a combination of films having high etching selectivity therebetween is selected for the first sacrificial layer and the second sacrificial layer. Thus, a film that can be used for the second sacrificial layer can be selected in accordance with the etching conditions of the first sacrificial layer and those of the second sacrificial layer.

For example, in the case where dry etching using a gas containing fluorine (also referred to as a fluorine-based gas) is performed for the etching of the second sacrificial layer, silicon, silicon nitride, silicon oxide, tungsten, titanium, molybdenum, tantalum, tantalum nitride, an alloy containing molybdenum and niobium, an alloy containing molybdenum and tungsten, or the like can be used for the second sacrificial layer. Here, a metal oxide film of IGZO, ITO, or the like is given as an example of a film having high etching selectivity (that is, enabling low etching rate) in dry etching using the fluorine-based gas, and such a film can be used as the first sacrificial layer.

Note that the material for the second sacrificial layer is not limited to the above and can be selected from a variety of materials in accordance with the etching conditions of the first sacrificial layer and those of the second sacrificial layer. For example, any of the films that can be used for the first sacrificial layer can be used.

As the second sacrificial layer, a nitride film can be used, for example. Specifically, it is also possible to use a nitride such as silicon nitride, aluminum nitride, hafnium nitride, titanium nitride, tantalum nitride, tungsten nitride, gallium nitride, or germanium nitride.

Alternatively, an oxide film can be used as the second sacrificial layer. Typically, an oxide film or an oxynitride film such as silicon oxide, silicon oxynitride, aluminum oxide, aluminum oxynitride, hafnium oxide, or hafnium oxynitride can be used.

### <Wet Process>

Although an inkjet method and a spin coating method are given as a wet process, for example, a coating method, a nozzle printing method, gravure printing, or the like is also included. In an ink-jet method, a spin coating method, or the like, a liquid composition is referred to as a droplet in many cases, but may be referred to as an ink material. Furthermore, although description “a droplet is dripped” is used, description “an ink material is applied” may be used.

Examples of a solvent that can be used in the case where the wet process is employed include: chlorine-based solvents such as dichloroethane, trichloroethane, chlorobenzene, and dichlorobenzene: ether-based solvents such as tetrahydrofuran, dioxane, anisole, and methylanisole: aromatic hydrocarbon-based solvents such as toluene, xylene, mesitylene, ethylbenzene, hexylbenzene, and cyclohexylbenzene: aliphatic hydrocarbon-based solvents such as cyclohexane, methylcyclohexane, pentane, hexane, heptane, octane, nonane, decane, dodecane, and bicyclohexyl: ketone-based solvents such as acetone, methyl ethyl ketone, benzophenone, and acetophenone: ester-based solvents such as ethyl acetate, butyl acetate, ethyl cellosolve acetate, methyl benzoate, and phenyl acetate: polyalcohol-based solvents such as ethylene glycol, glycerin, and hexanediol: alcohol-based solvents such as isopropyl alcohol and cyclohexanol: a sulfoxide-based solvent such as dimethylsulfoxide; and amide-based solvents such as methylpyrrolidone and dimethylformamide. One or more solvents can be used.

### <Inkjet Device>

The inkjet device includes a nozzle. A droplet is applied from an opening provided on the nozzle. The diameter of the opening (also referred to as a nozzle diameter) is several micrometers to several tens of micrometers. A portion including the nozzle is sometimes referred to as a head. A droplet injection control portion is provided in the head to drip the droplet, and a piezoelectric element or the like is included, for example. The droplet can be dripped by changing the capacity of an ink material tank connected to the nozzle with the piezoelectric element. The amount of the droplet is greater than or equal to several picoliters and less than or equal to several tens of picoliters according to the nozzle diameter in many cases. Although depending on the material, approximately one picoliter droplet can be considered to form an approximately 10 μm cube.

As the resolution of a display device is increased, the opening portion 104 is more miniaturized. On the other hand, the nozzle diameter of the inkjet device has a limitation in miniaturization because of mechanical processing. Therefore, the opening portion 104 is more miniaturized than the nozzle diameter. As a result, a droplet is dripped across a plurality of opening portions in some cases. In such a case, a method processing using a resist mask is suitable for obtaining a high-resolution display device.

### <Resist Mask RES>

As a material of the resist mask, a negative type or a positive type can be used. The resist mask is formed in such a manner that a resist material is formed and exposed to specific light. In the case of the negative type, the solubility of a portion exposed to light in a developer is decreased and accordingly the portion exposed to light remains after development. Thus, the portion exposed to light is used as the resist mask. In the case of the positive type, the solubility of a portion exposed to light in a developer is increased and accordingly a portion that has not been exposed to light remains after development. Thus, the portion that has not been exposed to light is used as the resist mask. As a light source used for the light exposure, an excimer laser, an electron beam, an ultraviolet ray, or the like can be used. The use of the resist mask enables minute processing with several tens of nanometers to 10 μm, preferably greater than or equal to 100 nm and less than or equal to 5 μm.

### <Light-Emitting Element>

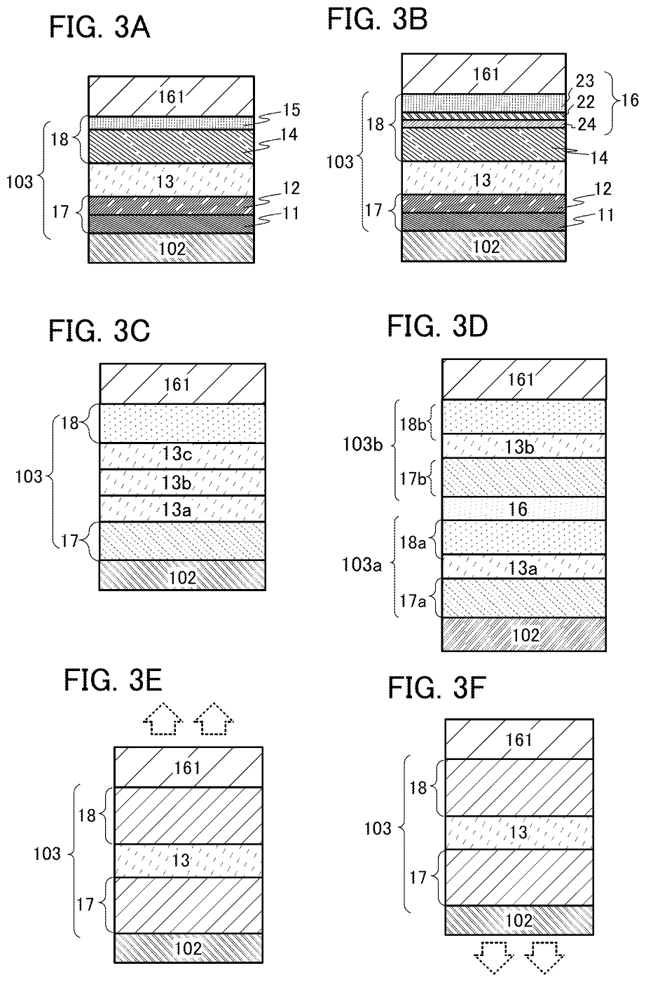

FIG. 3A schematically illustrates a light-emitting element having a single structure. The light-emitting element includes a light-emitting unit 103 between the first electrode 102 and the second electrode 161 that are a pair of electrodes. The first electrode 102 corresponds to the anode, and the second electrode 161 corresponds to the cathode. The light-emitting unit 103 includes a hole-transport region 17, a light-emitting layer 13, and an electron-transport region 18. The light-emitting layer 13 is referred to as a light-emitting region in some cases.

Although the hole-transport region 17 preferably includes a hole-injection layer 11 and a hole-transport layer 12, holes can be transported even with either of the hole-injection layer 11 or the hole-transport layer 12. One or both selected from the hole-injection layer 11 and the hole-transport layer 12 can be formed by a wet process. After that, one or both selected from the hole-injection layer 11 and the hole-transport layer 12 can be processed by a photolithography method or the like, and one or both selected from the hole-injection layer 11 and the hole-transport layer 12 are divided, whereby occurrence of crosstalk can be inhibited.

In FIG. 3A, the hole-transport region 17 includes the hole-injection layer 11 and the hole-transport layer 12, and specifically, the hole-injection layer 11 and the hole-transport layer 12 are provided in this order from the first electrode 102. One or both selected from the hole-injection layer 11 and the hole-transport layer 12 can be formed by a wet process.

Although the electron-transport region 18 preferably includes an electron-transport layer 14 and an electron-injection layer 15, electrons can be transported even with either of the electron-transport layer 14 or the electron-injection layer 15. In FIG. 3A, the electron-transport layer 14 and the electron-injection layer 15 are provided in this order from the light-emitting layer 13.

One or both selected from the electron-transport layer 14 and the electron-injection layer 15 can be formed by a wet process. After that, one or both selected from the electron-transport layer 14 and the electron-injection layer 15 can be processed, whereby occurrence of crosstalk can be inhibited.

The light-emitting unit 103 further includes another functional layer. As examples of another functional layer, one or more selected from a carrier-blocking layer, an exciton-blocking layer, a charge-generation layer, and the like can be given. One or two or more selected from the carrier-blocking layer, the exciton-blocking layer, and the charge-generation layer can be formed by a wet process. After that, one or two or more selected from the carrier-blocking layer, the exciton-blocking layer, and the charge-generation layer are processed by a photolithography method, whereby occurrence of crosstalk can be inhibited.

The light-emitting layer 13 contains at least a light-emitting material, i.e., a light-emitting organic compound. A droplet containing a light-emitting material and a solvent is prepared, and the light-emitting layer 13 can be formed by a wet process. After that, the light-emitting layer 13 is processed by a photolithography method, whereby occurrence of crosstalk can be inhibited.

The hole-transport region 17 contains at least an organic compound having a hole-transport property. The organic compound having a hole-transport property is referred to as a hole-transport material in some cases. A droplet containing a hole-transport material and a solvent is prepared, and the hole-transport region 17 can be formed by a wet process.

In the case of the light-emitting element including the hole-injection layer 11 and the hole-transport layer 12, when the hole-injection layer 11 and the hole-transport layer 12 each contain at least a hole-transport material, the functions of the layers can be exhibited.

The electron-transport region 18 contains at least an organic compound having an electron-transport property. The organic compound having an electron-transport property is referred to as an electron-transport material in some cases. A droplet containing an electron-transport material and a solvent is prepared, and the electron-transport region 18 can be formed by a wet process. In the case of the light-emitting element including the electron-transport layer 14 and the electron-injection layer 15, when the electron-transport layer 14 and the electron-injection layer 15 each contain at least an electron-transport material, the functions of the layers can be exhibited.

Since the hole-transport region 17 contains a hole-transport material, the hole-transport region 17 has a function of transporting holes between the first electrode 102 and the light-emitting layer 13. Therefore, the organic compound used in the hole-transport region 17 preferably contains a material including a skeleton having a relatively high hole-transport property. As a skeleton having a high hole-transport property, for example, a skeleton having a π-electron rich heteroaromatic ring skeleton selected from an arylamine skeleton, a pyrrole skeleton, a carbazole skeleton, a thiophene skeleton, and the like can be given.

Since the electron-transport region 18 contains an electron-transport material, the electron-transport region 18 has a function of transporting electrons between the second electrode 161 and the light-emitting layer 13. Therefore, the organic compound used in the electron-transport region 18 preferably contains a material having a relatively high electron-transport property.

In one embodiment of the present invention, any one of the above organic compounds is formed by a wet process, leading to reduced manufacturing cost of the display device.

As illustrated in FIG. 3B, a charge-generation layer 16 may be provided corresponding to the electron-injection layer 15 in FIG. 3A. The charge-generation layer 16 refers to a layer capable of injecting holes into a layer in contact therewith on the cathode side and injecting electrons into a layer in contact therewith on the anode side when supplied with a potential. The charge-generation layer 16 includes at least a p-type layer 23. The p-type layer 23 is preferably formed using any of the organic compounds given above as examples of the material that can be used in the hole-injection layer 11. The p-type layer 23 may be a film containing a material exhibiting an acceptor property in addition to the organic compound. The p-type layer 23 may have a structure in which a film containing a material exhibiting an acceptor property and a film containing a hole-transport material are stacked. When a potential is applied to the p-type layer 23, electrons are injected to the electron-transport layer 14 and holes are injected to the second electrode 161: whereby the light-emitting element can be operated. The charge-generation layer 16 can be formed by a wet process. Furthermore, the p-type layer 23 including in the charge-generation layer 16 can be formed by a wet process.

The charge-generation layer 16 preferably includes any one or both of an electron-relay layer 22 and an electron-injection buffer layer 24 in addition to the p-type layer 23, in which case a property for injecting electrons to the electron-transport layer 14 becomes high. In FIG. 3B, one or both of the electron-relay layer 22 and the electron-injection buffer layer 24 are provided in addition to the p-type layer 23, and the electron-relay layer 22 and the electron-injection buffer layer 24 are positioned between the second electrode 161 and the electron-transport layer 14. One or both selected from the electron-relay layer 22 and the electron-injection buffer layer 24 included in the charge-generation layer 16 can be formed by a wet process.

The light-emitting element may have a structure in which a plurality of light-emitting layers are stacked as illustrated in FIG. 3C. In FIG. 3C, a light-emitting layer 13a, a light-emitting layer 13b, and a light-emitting layer 13c are stacked in this order from the first electrode 102 side. The stacked-layer structure in which a charge-generation layer is not provided between the layers may be regarded as one light-emitting unit, and the light-emitting element illustrated in FIG. 3C is a variation of the single structure. One or two or more selected from the light-emitting layer 13a, the light-emitting layer 13b, and the light-emitting layer 13c can be formed by a wet process.

In FIG. 3A to FIG. 3C, the hole-transport region 17 includes two layers of the hole-injection layer 11 and the hole-transport layer 12. In the case where a layer in contact with the first electrode 102, such as the hole-injection layer 11 or the hole-transport layer 12, is formed by a wet process, a material exhibiting an acceptor property is preferably contained in the skeleton having a high hole-transport property at the same time. Examples of the material having an acceptor property include a sulfonic acid compound, a fluorine compound, a trifluoroacetic acid compound, a propionic acid compound, and a metal oxide.

As a material of the droplet to be applied in a wet process (referred to as an ink material), a polymer material, a low molecular weight material, a dendrimer, or the like can be used as it is. As the ink material, a material in which a polymer material, a low molecular weight material, a dendrimer, or the like is dispersed in a solvent or a material in which a polymer material, a low molecular weight material, a dendrimer, or the like is dissolved in a solvent may be used. A polymer material may be obtained by mixing one or more of monomers. For mixing of one or more of monomers, the ink material in the mixed state may be applied and then subjected to heating, energy light irradiation, or the like to form a bond such as cross-linking, condensation, polymerization, coordination, or a salt.

Note that the above ink material may include a material having a different function, such as a surface active agent or a material for adjusting viscosity.

As an amine compound used as the ink material, any of a primary amine, a secondary amine, and a tertiary amine can be used, and in particular, a secondary amine is preferred. In the case where the ink material in which a plurality of monomers are mixed is applied and polymerization is formed after the application, a secondary amine and arylsulfonic acid are preferably used as the monomers.

The secondary amine preferably has a substituted or unsubstituted aryl group having 6 to 14 carbon atoms or a substituted or unsubstituted π-electron rich type heteroaryl group having 6 to 12 carbon atoms. Examples of the aryl group include a phenyl group, a biphenyl group, a naphthyl group, a fluorenyl group, a phenanthrenyl group, and an anthryl group. The above phenyl group is preferred because it improves solubility and reduces the raw material cost. Examples of the heteroaryl group include a carbazole skeleton, a pyrrole skeleton, a thiophene skeleton, a furan skeleton, and an imidazole skeleton.

The secondary amine preferably includes a plurality of bonds with an arylamine or a heteroaryl amine for the improvement of film quality after the application, heating, or curing. When the secondary amine includes many such bonds, an oligomer or a polymer is preferably formed.

The secondary amine may have a plurality of amine skeletons. In this case, some of the amine skeletons may be a primary amine or a tertiary amine. Note that the proportion of the secondary amine is preferably higher than the proportion of the primary amine or the tertiary amine. The number of amine skeletons is preferably less than or equal to 1000, further preferably less than or equal to 10, and the molecular weight of the secondary amine is preferably less than or equal to 100000. An amine skeleton substituted by fluorine is preferably used because it improves compatibility with a compound in which fluorine is substituted.

The secondary amine is preferably, for example, an organic compound represented by General Formula (G1) below, which is suitable for a wet process.

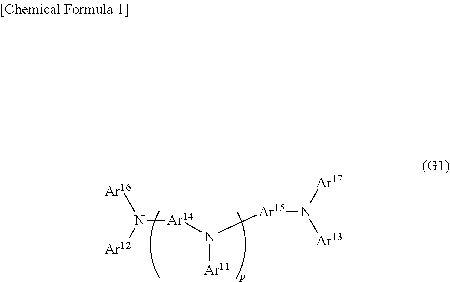

In General Formula (G1) above, one or more of Ar¹¹ to Ar¹³ represent hydrogen, and Ar¹⁴ to Ar¹⁷ represent substituted or unsubstituted aromatic rings each having 6 to 14 carbon atoms. As the aromatic ring having 6 to 14 carbon atoms, a benzene ring, a bisbenzene ring, a naphthalene ring, a fluorene ring, a phenanthrene ring, or an anthracene ring can be used. Note that Ar¹² and Ar¹⁶ may be bonded to each other to form a ring, Ar¹⁴ and Ar¹⁶ may be bonded to each other to form a ring, Ar¹¹ and Ar¹⁴ may be bonded to each other to form a ring, Ar¹⁴ and Ar¹⁵ may be bonded to each other to form a ring, Ar¹⁵ and Ar¹⁷ may be bonded to each other to form a ring, and Ar¹³ and Ar¹⁷ may be bonded to each other to form a ring. Furthermore, p represents an integer of 0 to 1000, and preferably represents 0 to 3. Note that the molecular weight of the organic compound represented by General Formula (G1) above is preferably less than or equal to 100000.

The tertiary amine is preferably, for example, an organic compound represented by General Formula (G2) below, which is suitable for a wet process.

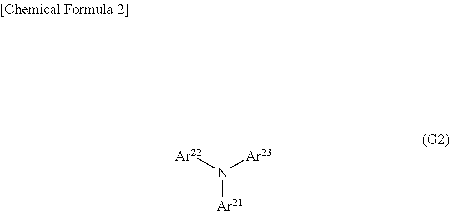

Note that in General Formula (G2) shown above, Ar²¹ to Ar²³ represent a substituted or unsubstituted aryl groups each having 6 to 14 carbon atoms and may be bonded to each other to form rings. In the case where Ar²¹ to Ar²³ each include a substituent, the substituent may be a group in which a plurality of diarylamino groups or carbazolyl groups are bonded. The organic compound represented by General Formula (G2) above may include an ether bond, a sulfide bond, or a bond via an amine; any of these bonds preferably exists between a plurality of aryl groups, in which case the solubility in a solvent is improved. The organic compound represented by General Formula (G2) above may include an alkyl group as a substituent, in which case the alkyl group may be bonded through an ether bond, a sulfide bond, or a bond via an amine.

As specific examples of the secondary amine, organic compounds represented by Structural Formula (Am2-1) to Structural Formula (Am2-32) below are preferably used. The organic compounds represented by Structural Formula (Am2-1) to Structural Formula (Am2-32) each have an NH group.

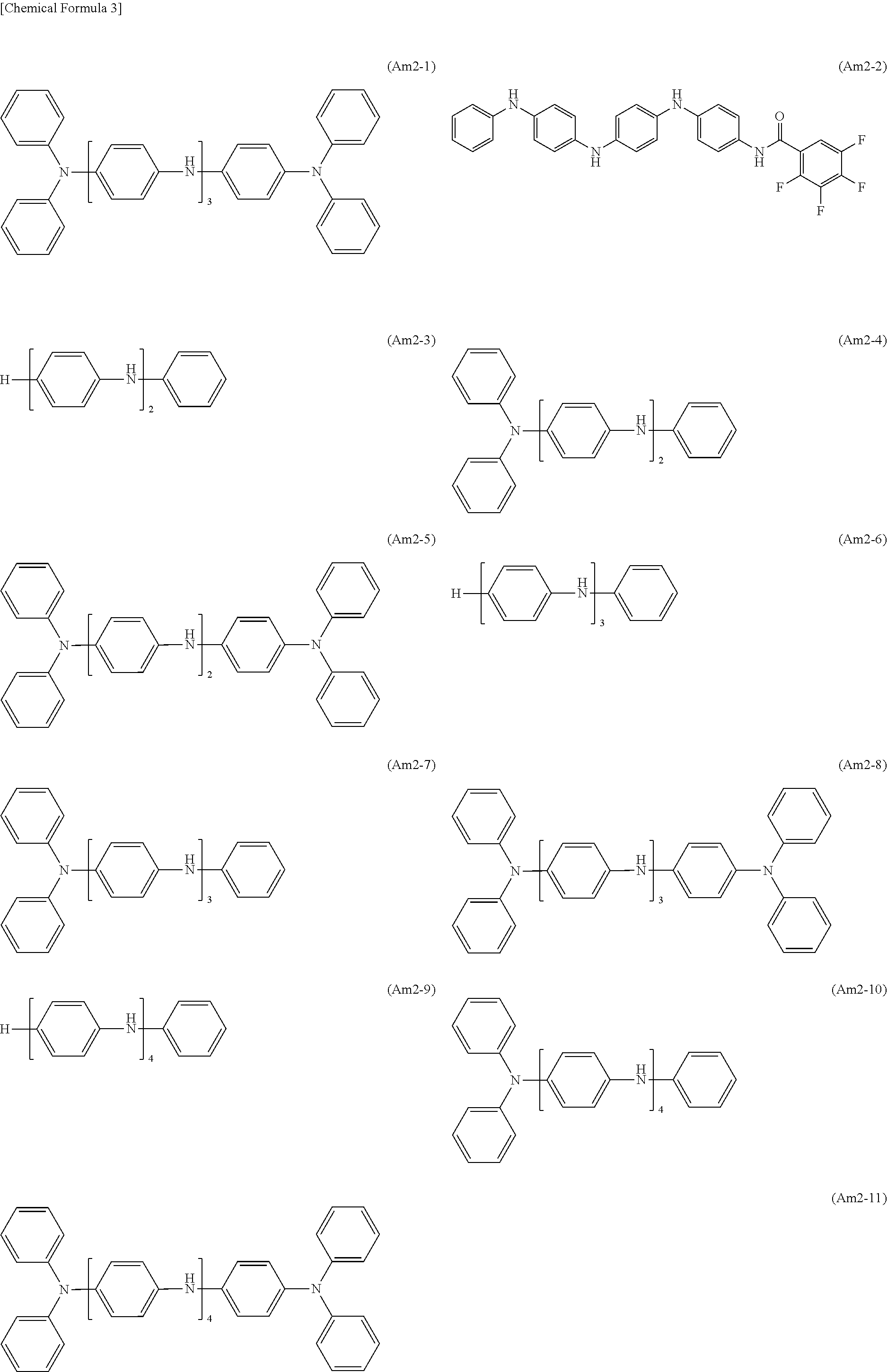

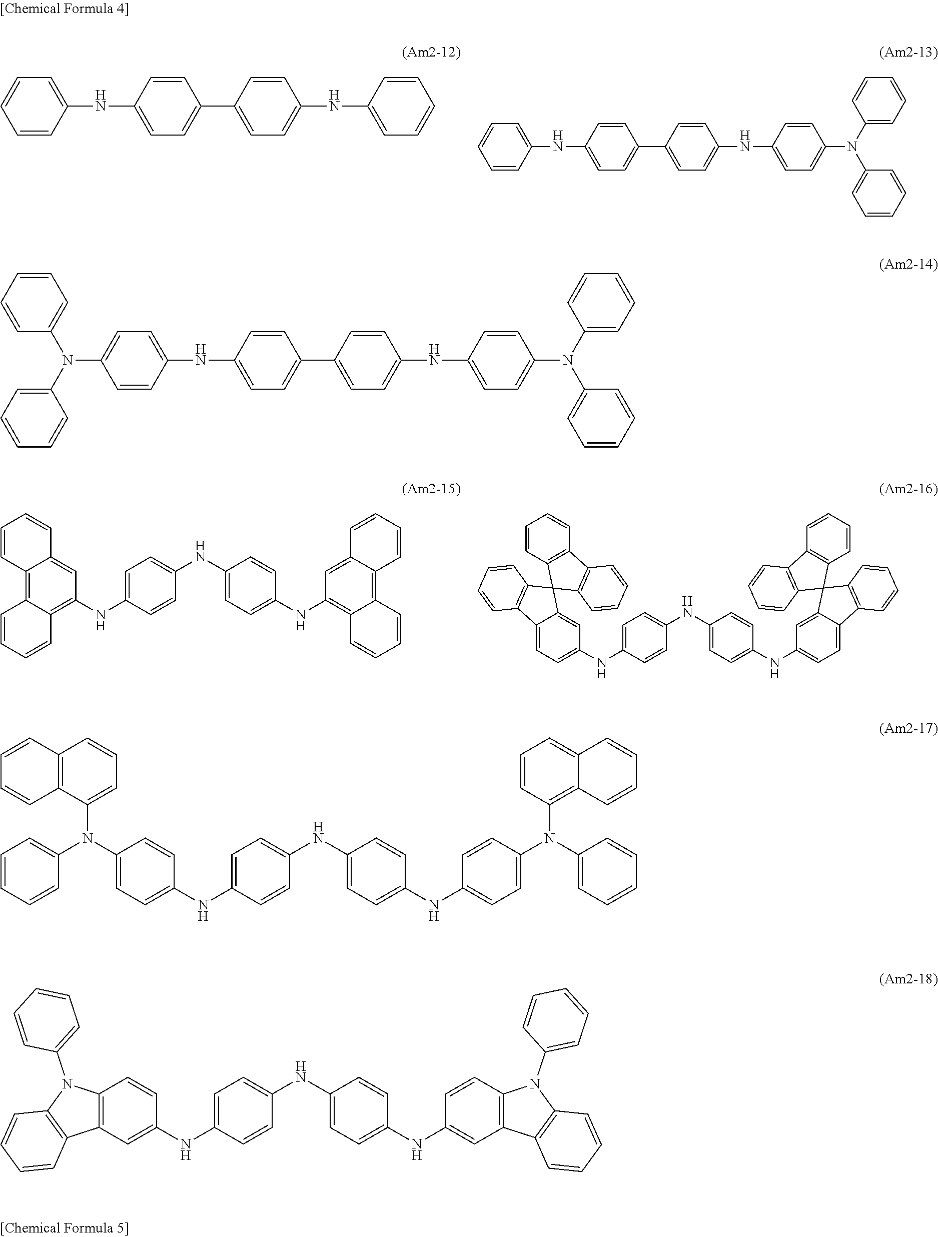

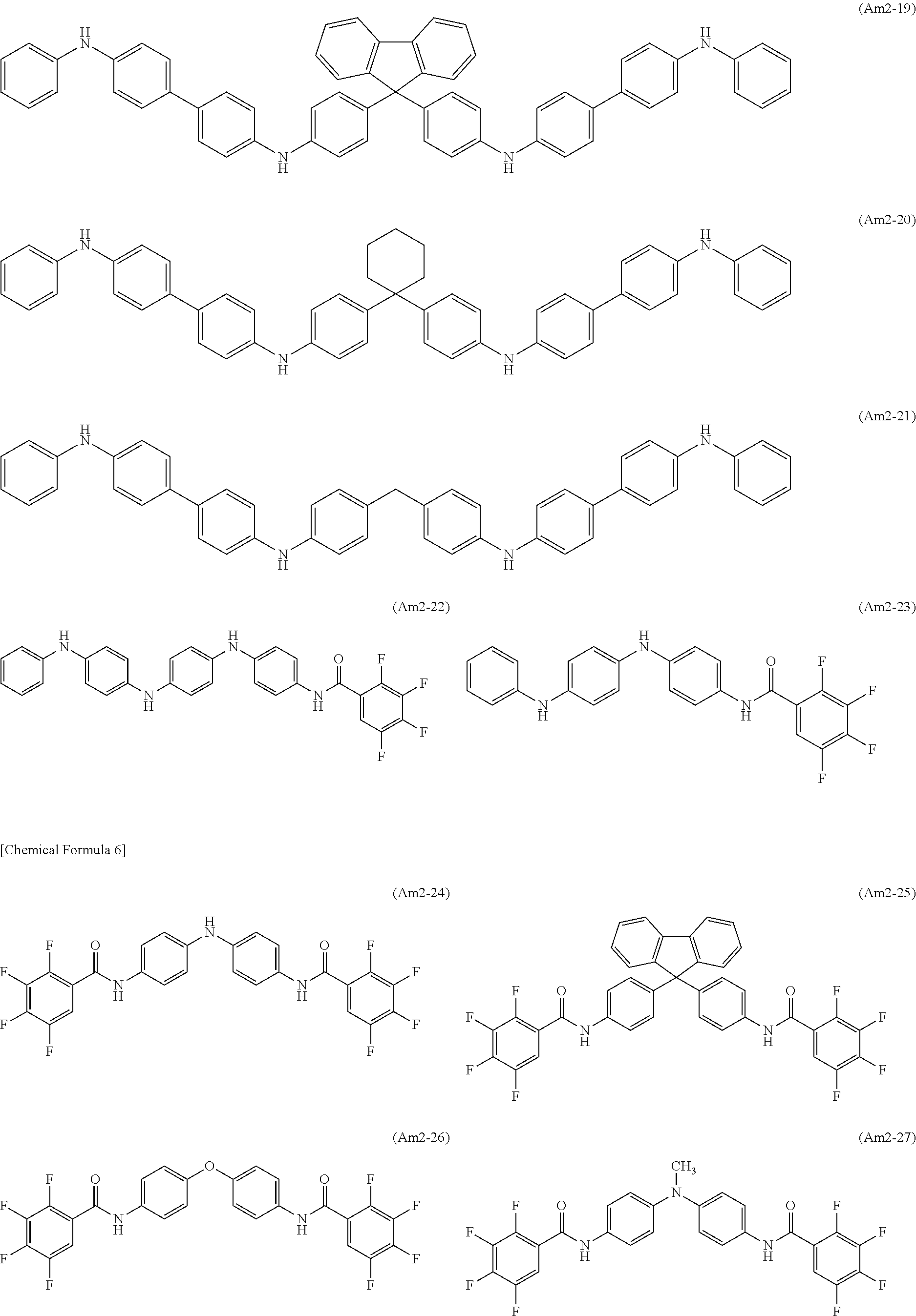

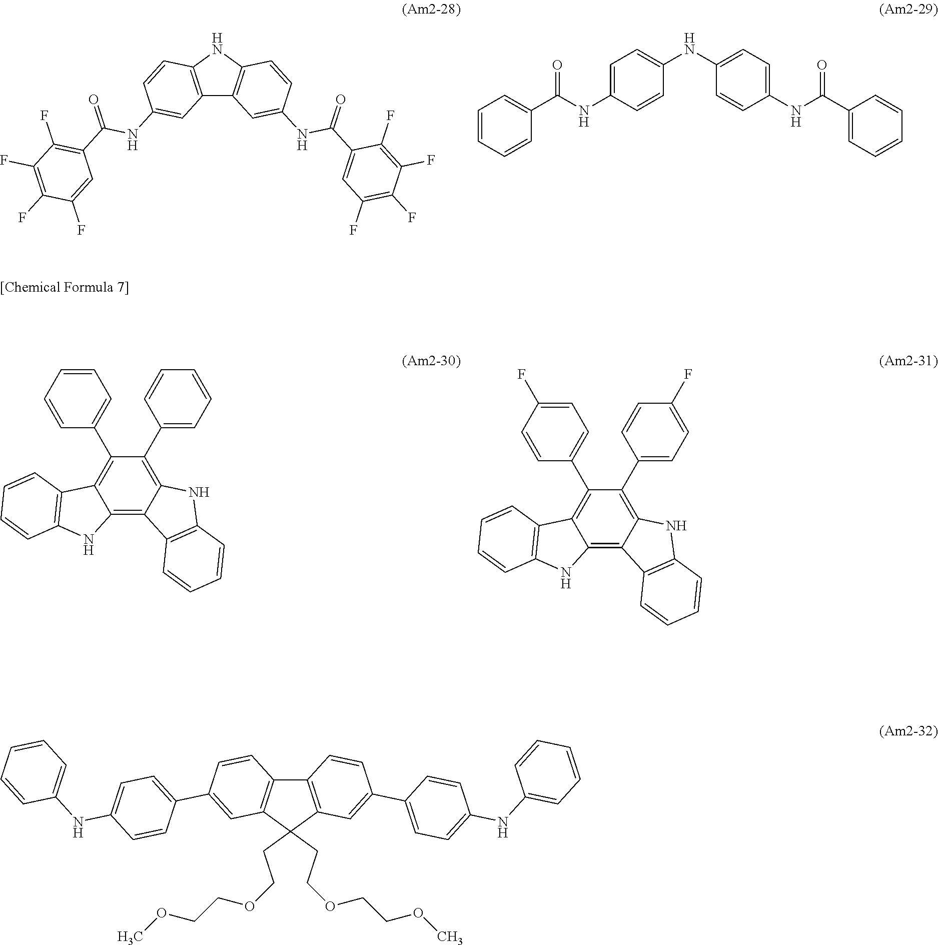 [SMILES: O=C(Nc1ccc2[nH]c3ccc(NC(=O)c4cc(F)c(F)c(F)c4F)cc3c2c1)c1cc(F)c(F)c(F)c1F ; O=C(Nc1ccc(Nc2ccc(NC(=O)c3ccccc3)cc2)cc1)c1ccccc1 ; c1ccc(-c2c(-c3ccccc3)c3c4ccccc4[nH]c3c3c2[nH]c2ccccc23)cc1 ; Fc1ccc(-c2c(-c3ccc(F)cc3)c3c4ccccc4[nH]c3c3c2[nH]c2ccccc23)cc1 ; COCCOCCC1(CCOCCOC)c2cc(-c3ccc(Nc4ccccc4)cc3)ccc2-c2ccc(-c3ccc(Nc4ccccc4)cc3)cc21]

An amine compound can be used for the ink material by being mixed with a sulfonic acid compound. Mixing with a sulfonic acid compound facilitates generation of carriers and improves conductivity. Mixing with a sulfonic acid compound is referred to as p doping in some cases. In the case of using the secondary amine as the amine compound, bondings with a mixed sulfonic acid compound can be formed by a dehydration reaction, or the like, which is preferable. In the case where the compound mixed with the amine compound is a fluoride, a fluoride is preferably used as in Structural Formula (Am2-2), Structural Formulae (Am2-22) to (Am-2-28), or Structural Formula (Am2-31) shown above to improve compatibility.

Note that a thiophene derivative may be used instead of the secondary amine. Specific examples of a thiophene derivative, organic compounds represented by Structural Formula (T-1) to Structural Formula (T-4) shown below, polythiophene, or poly(3,4-ethylenedioxythiophene) (PEDOT) is preferable. A thiophene derivative facilitates generation of carriers and improves conductivity by being mixed with a sulfonic acid compound. Mixing with a sulfonic acid compound is referred to as p doping in some cases.

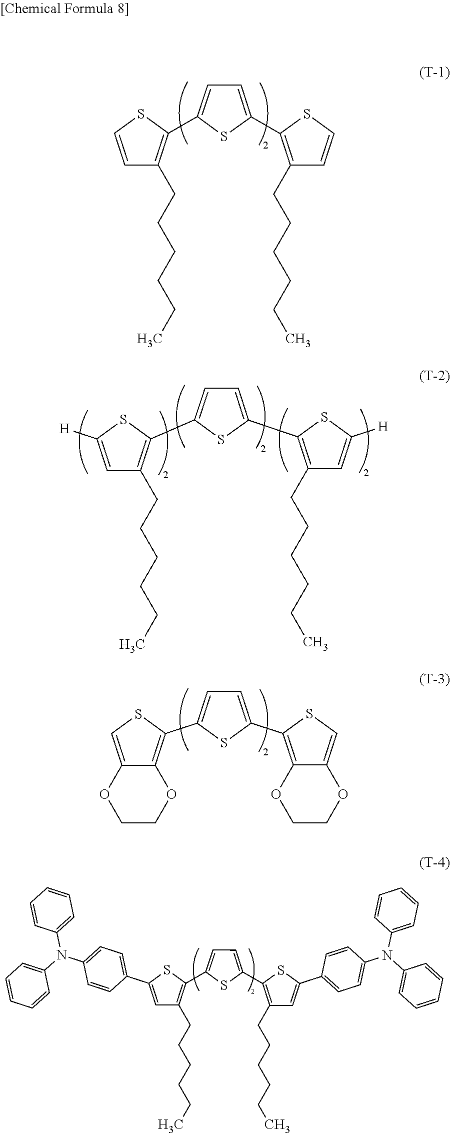

The sulfonic acid compound is a material exhibiting an acceptor property. As a sulfonic acid compound, an arylsulfonic acid can be given. It is only required that the arylsulfonic acid has a sulfo group: a sulfonic acid, a sulfonate, an alkoxysulfonic acid, a halogenated sulfonic acid, or a sulfonic acid anion can be used. Two or more of these sulfo groups may be included. As the aryl group of the arylsulfonic acid, a substituted or unsubstituted aryl group having 6 to 16 carbon atoms can be used. As the aryl group, for example, a phenyl group, a biphenyl group, a naphthyl group, a fluorenyl group, a phenanthrenyl group, an anthryl group, or a pyrenyl group can be used, and a naphthyl group is preferable because it has favorable solubility in a solvent and a favorable transport property. The arylsulfonic acid may include two or more of the aryl groups. The arylsulfonic acid preferably includes an aryl group substituted by fluorine because the LUMO (Lowest Unoccupied Molecular Orbital) level can be adjusted to be deep (in the negative direction widely). The arylsulfonic acid may include an ether bond, a sulfide bond, or a bond via an amine; any of these bonds preferably exists between a plurality of aryl groups, in which case the solubility in a solvent is improved. Also when the arylsulfonic acid includes an alkyl group as a substituent, the alkyl group may be bonded through an ether bond, a sulfide bond, or a bond via an amine. The arylsulfonic acid may be substituted in part of a polymer. Polyethylene, nylon, polystyrene, or polyfluorenylene can be used as the polymer; polystyrene or polyfluorenylene is preferred because of its favorable conductivity.

Specific and preferred examples of compounds including the arylsulfonic acid (arylsulfonic acid compounds) include organic compounds represented by Structural Formula (S-1) to Structural Formula (S-15) below. A polymer having a sulfo group such as poly(4-styrenesulfonic acid) (PSS) can also be used. Electrons from an electron donor with a shallow HOMO (highest occupied Molecular Orbital) (such as an amine compound, a carbazole compound, or a thiophene compound) can be accepted by using an arylsulfonic acid compound, and the property of hole injection or hole transport from an electrode can be obtained by mixing with an electron donor. When the arylsulfonic acid compound is a fluorine compound, the LUMO level can be adjusted to be deeper (the energy level can be higher in the negative direction).

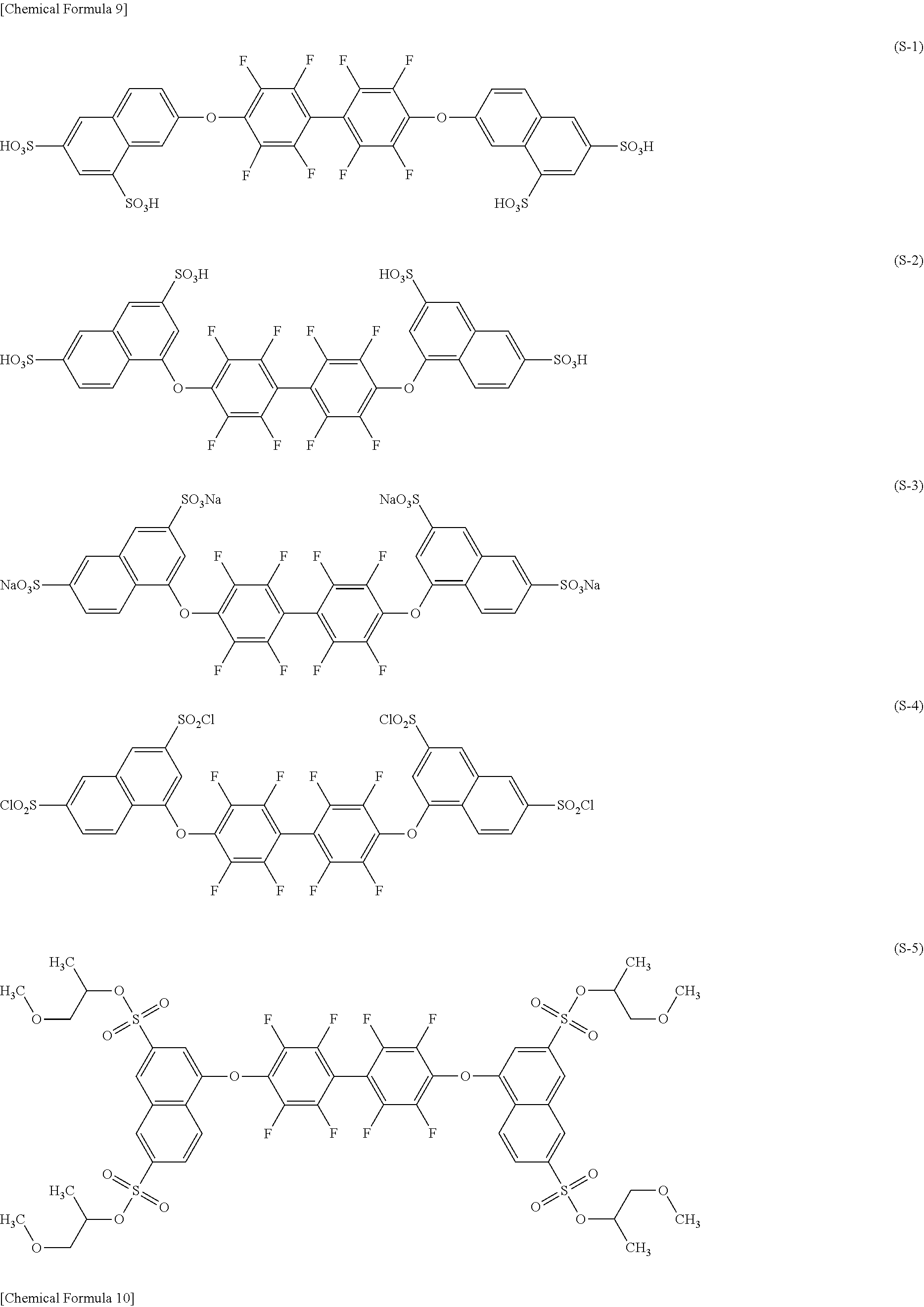

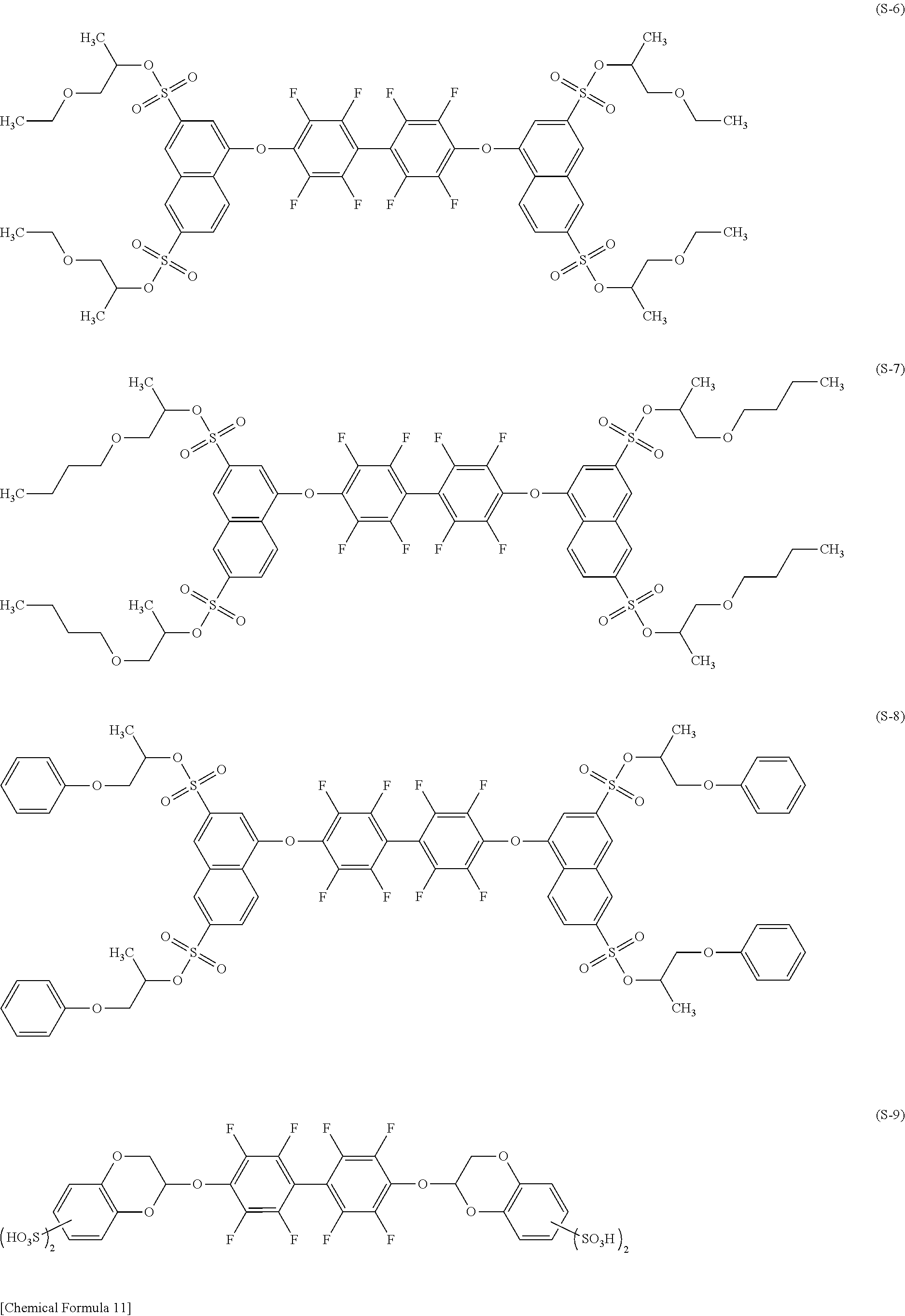

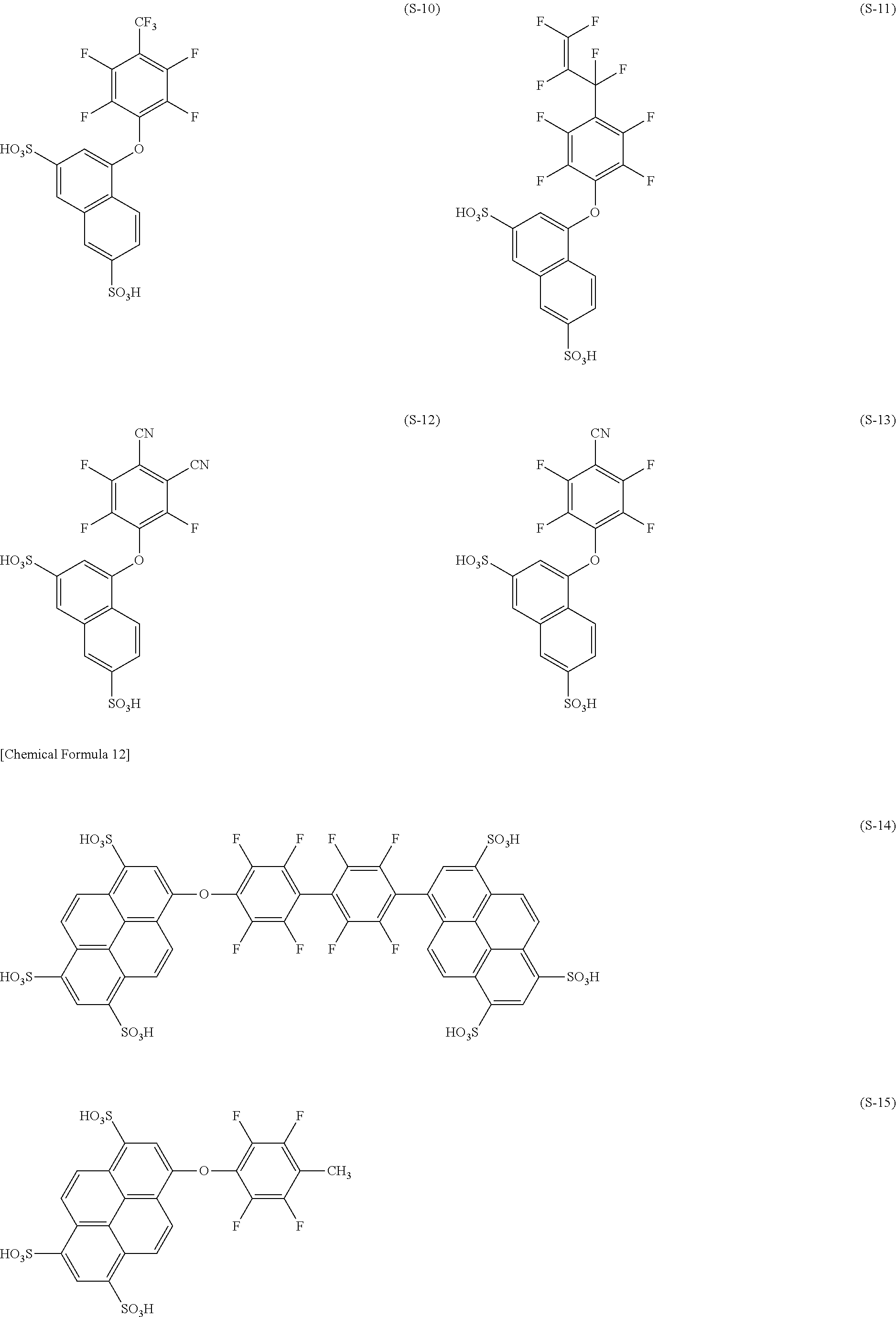

A tertiary amine may further be mixed into the ink material mixing a secondary amine and sulfonic acid. A tertiary amine is electrochemically and photochemically stable as compared to a secondary amine and thereby enables a favorable hole-transport property when mixed. As the tertiary amine, for example, organic compounds represented by Structural Formula (Am3-1) to Structural Formula (Am3-7) shown below are preferable. A material having a hole-transport property other than a tertiary amine may be mixed as appropriate into the ink material.

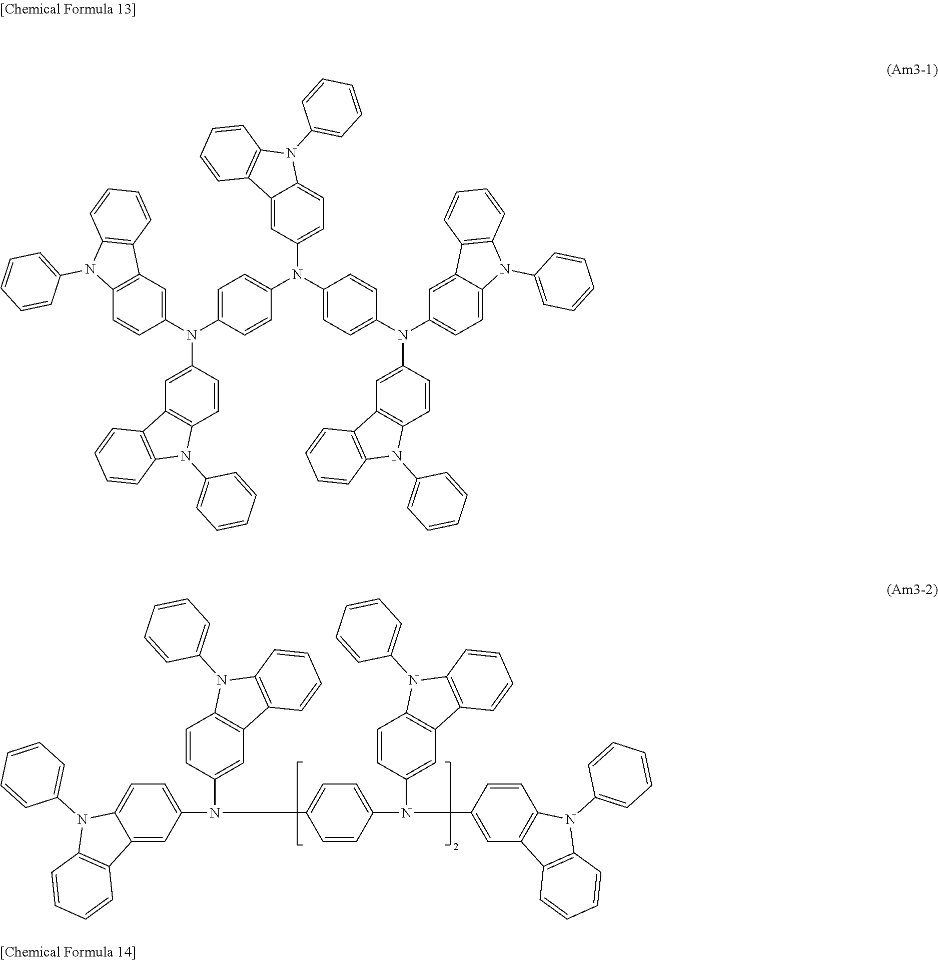

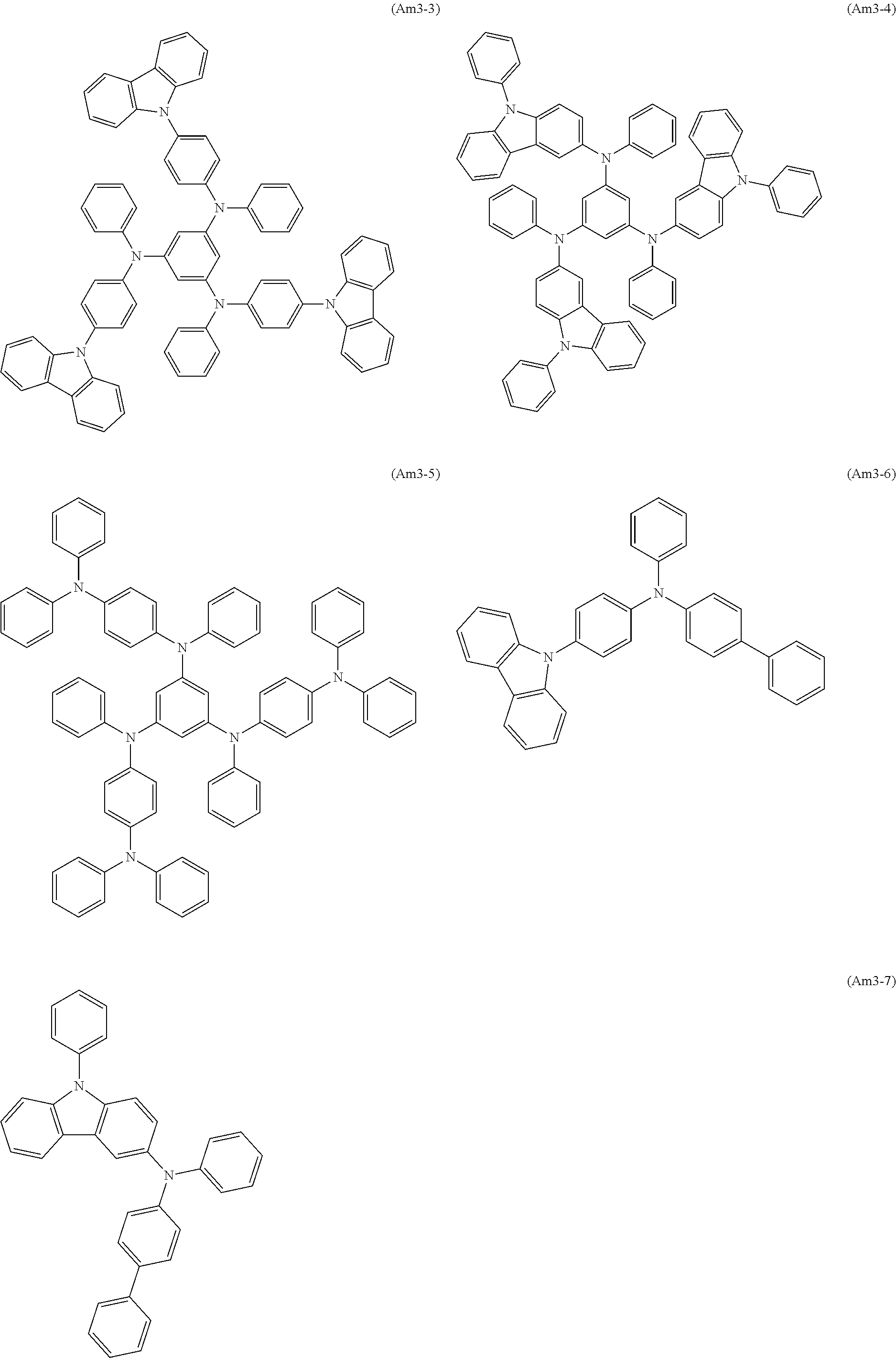

Other than the arylsulfonic acid compound, a cyano compound such as a tetracyanoquinodimethane compound can be used as an electron acceptor. Specifically, 2,3,5,6-tetrafluoro-7,7,8,8-tetracyano-quinodimethane (F4TCNQ), dipyrazino[2,3-f:2′,3′-h]quinoxaline-2,3,6,7,10,11-hexacarbonitrile (HAT-CN6), or the like can be given.

Note that the ink material in which a monomer is mixed preferably includes one or both of a 3,3,3-trifluoropropyltrimethoxysilane compound and a phenyltrimethoxysilane compound because the wettability can be improved when deposited by a wet process.

When a layer deposited by a wet process with the ink material including at least two monomers of an electron donor such as the secondary amine or thiophene and arylsulfonic acid is measured by ToF-SIMS, a signal is observed at around m/z=80 in a negative-mode result. The m/z=80 corresponds to a signal derived from an SO₃ anion in arylsulfonic acid. By contrast, a signal derived from an amine monomer is less likely to be observed from the above layer. Meanwhile, sufficient light emission by the light-emitting element including the layer gives evidence that the layer has a sufficient hole-transport property. If a light-emitting element capable of light emission shows the analysis results including the signal and the like described above, the layer is found to have a sufficient hole-transport property, and the absence of the observed skeletons having a hole-transport property such as an amine suggests that the monomers are bonded to each other to form a high molecular weight compound film. These analysis results mean that the layer is formed by a wet process.

A sulfonic acid compound represented by Structural Formula (S-1) or (S-2) shown above is preferable because the sulfonic acid compound has many sulfo groups and a three-dimensional bonding with an amine compound can be formed, so that film quality is likely to be stable. With the layer formed by using an arylsulfonic acid compound, a signal at m/z=901 can be observed in a negative mode in addition to the above signal of m z=80. In addition, a signal at around m/z=328 can be observed as a product ion.

Note that in the light-emitting element of one embodiment of the present invention, it is preferable that the iridium complex represented by a structural formula shown below be used as a light-emitting material. The iridium complex shown below is preferable because it has an alkyl group, so that it can easily be dissolved in a solvent and make it easy to adjust ink material.

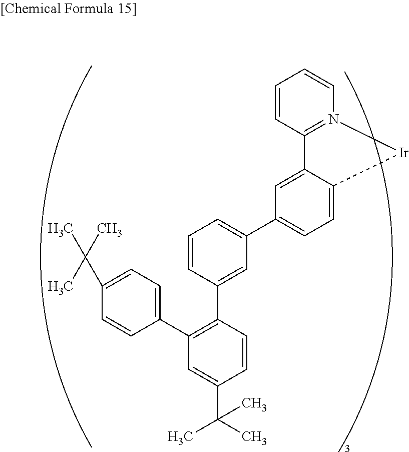

When the light-emitting layer containing the iridium complex represented by the above structural formula is measured by ToF-SIMS, it has been found that a signal appears at m/z=1676, or m/z=1181 and m z=685 each of which corresponds to a product ion, in the result of a positive mode.

### <Tandem Structure>

FIG. 3D illustrates a light-emitting element with a tandem structure in which a plurality of light-emitting units are stacked (also referred to as a stacked light-emitting element). This light-emitting element includes at least a first light-emitting unit 103a and a second light-emitting unit 103b between the anode and the cathode. One light-emitting unit has substantially the same structure as that of the light-emitting unit 103, which is illustrated in FIG. 3A and the like.

In the light-emitting element with a tandem structure, the first light-emitting unit 103a and the second light-emitting unit 103b are stacked between the first electrode 102 and the second electrode 161, and the charge-generation layer 16 is included between the first light-emitting unit 103a and the second light-emitting unit 103b. The charge-generation layer 16 can be formed by a wet process. After that, the charge-generation layer 16 is processed, whereby occurrence of crosstalk can be inhibited.

The first light-emitting unit 103a and the second light-emitting unit 103b may have the same structure or different structures. In the case where the first light-emitting unit 103a and the second light-emitting unit 103b have different structures, they preferably emit light of complementary colors to exhibit white light emission when combined. The light-emitting element exhibiting white light emission can perform full-color display with the use of color filters.

The charge-generation layer 16 has a function of injecting electrons into one of the light-emitting units and injecting holes into the other light-emitting unit when a voltage is applied to the first electrode 102 and the second electrode 161. That is, the charge-generation layer 16 injects electrons into the first light-emitting unit 103a and holes into the second light-emitting unit 103b when voltage is applied such that the potential of the first electrode 102 becomes higher than the potential of the second electrode 161.

The charge-generation layer 16 preferably has a structure similar to that of the charge-generation layer 16 described with reference to FIG. 3B. As material used in the charge-generation layer 16, a composite material of an organic compound and a metal oxide can be given. The composite material having an excellent carrier-injection property and an excellent carrier-transport property is preferable because low-voltage driving and low-current driving can be achieved.

Note that the charge-generation layer may be included in the light-emitting unit on the anode side. In the structure, the charge generation layer can serve as the hole-injection layer of the light-emitting unit, and thus the hole-injection layer is not necessarily provided in the light-emitting unit on the anode side.

The charge-generation layer 16 may include the electron-injection buffer layer 24 described with reference to FIG. 3B.

The electron-injection buffer layer 24 serves as the electron-injection layer in the light-emitting unit on the anode side, and thus the electron-injection layer is not necessarily provided in the light-emitting unit on the anode side.

The tandem element having two light-emitting units is described above: one embodiment of the present invention can also be applied to a tandem element in which three or more light-emitting units are stacked.

When a plurality of light-emitting units are provided between a pair of electrodes and the charge-generation layers are provided between the units, it is possible to provide a long-life light-emitting element that can emit light with high luminance at a low current density. Moreover, a light-emitting apparatus that can be driven at a low voltage and has low power consumption can be achieved.

When emission colors of light-emitting units are made different, light emission of a desired color can be obtained from the light-emitting element as a whole. For example, in a light-emitting element having two light-emitting units, the emission colors of the first light-emitting unit may be red and green and the emission color of the second light-emitting unit may be blue, so that the light-emitting element can emit white light as the whole element.

A light-emitting material contained in the light-emitting unit described with reference to FIG. 3 may include a phosphorescent material or a fluorescent material. The light-emitting layer of the light-emitting unit can be formed by a wet process using a phosphorescent light-emitting material or a fluorescent light-emitting material and a solvent. After that, the light-emitting layer is processed by a photolithography method, whereby occurrence of crosstalk can be inhibited.

### <Top-Emission Structure>

In FIG. 3E, the direction to which light is extracted from the light-emitting element is denoted by upward arrows, and a top-emission structure is illustrated in which light is extracted from the second electrode 161 side. The first electrode 102 corresponds to the first electrode 102 illustrated in FIG. 1 and the like, and light is not blocked by a semiconductor element placed below the first electrode 102; thus, the aperture ratio is probably increased. Accordingly, the aperture ratio can be increased depending on the direction to which light is extracted from the light-emitting element.

### <Bottom-Emission Structure>

In FIG. 3F, the light extraction direction is denoted by downward arrows, and a bottom-emission structure is illustrated in which light is extracted from the first electrode 102 side. The first electrode 102 corresponds to the first electrode 102 illustrated in FIG. 1 and the like, and light is blocked by a semiconductor element placed below the first electrode 102 in some cases: however, when a semiconductor element having a high light-transmitting property is used, the aperture ratio can be kept high.

The description in this embodiment can be used in combination with the other embodiments.

### Embodiment 2

In this embodiment, Manufacturing Method 2 of the display device of one embodiment of the present invention will be described. Manufacturing Method 2 is different from Manufacturing Method 1 in the order of the formation step of the sacrificial layer 150.

### <Manufacturing Method 2 of Display Device>

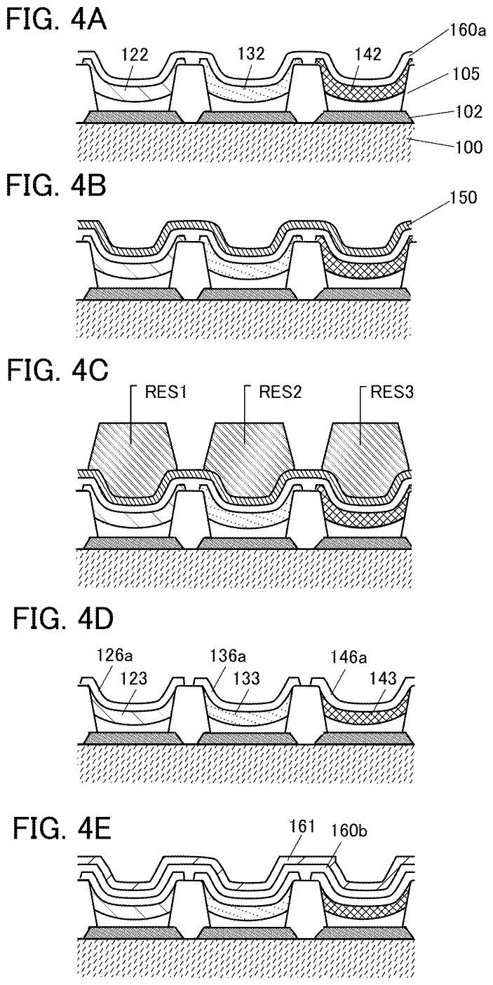

As in Embodiment 1 described above, the light-emitting layers are formed by a wet process, e.g., an inkjet method. After that, as illustrated in FIG. 4A, an electron-transport layer 160a that is an upper common layer of the light-emitting elements is formed. Embodiment 1 and the like can be referred to for the formation method, the material, and the like of the electron-transport layer 160a.

As illustrated in FIG. 4B, the sacrificial layer 150 is formed. Embodiment 1 and the like can be referred to for the formation method, the material, and the like of sacrificial layer 150.

As illustrated in FIG. 4C, the resist mask RES1, the resist mask RES2, and the resist mask RES3 are formed. Embodiment 1 and the like can be referred to for the formation methods, the materials, and the like of the resist mask RES1, the resist mask RES2, and the resist mask RES3.

As illustrated in FIG. 4D, with the use of the first resist mask RES1, the material layer 122 and the electron-transport layer 160a are processed by a photolithography method or the like, or more specifically are partly removed, thereby forming the processed material layer 123 and a processed first electron-transport layer 126a. With the use of the second resist mask RES2, the material layer 132 and the electron-transport layer 160a are processed, or more specifically are partly removed, thereby forming the processed material layer 133 and a processed second electron-transport layer 136a. With the use of the third resist mask RES3, the material layer 142 and the electron-transport layer 160a are processed, or more specifically are partly removed, thereby forming the processed material layer 143 and a processed third electron-transport layer 146a.

Since the processing step is performed in the state where the sacrificial layer 150 is provided, the material layers and the like are not removed, which is preferable. The sacrificial layer 150 is removed at the same time as the first resist mask RES1 to the third resist mask RES3.

After removing, the material layer 123, the material layer 133, and the material layer 143 each corresponding to the light-emitting layers can be obtained. Over the light-emitting layers, the first electron-transport layer 126a, the second electron-transport layer 136a, and the third electron-transport layer 146a can be obtained. The electron-transport layers are the upper common layers of the light-emitting elements and may be each processed using a resist mask. Occurrence of crosstalk can be inhibited.

As illustrated in FIG. 4E, an electron-injection layer 160b and the second electrode 161 are formed. Embodiment 1 and the like can be referred to for the formation method, the material, and the like of the electron-injection layer 160b and the second electrode 161.

Manufacturing Method 2 described above is described with reference to a flow chart.

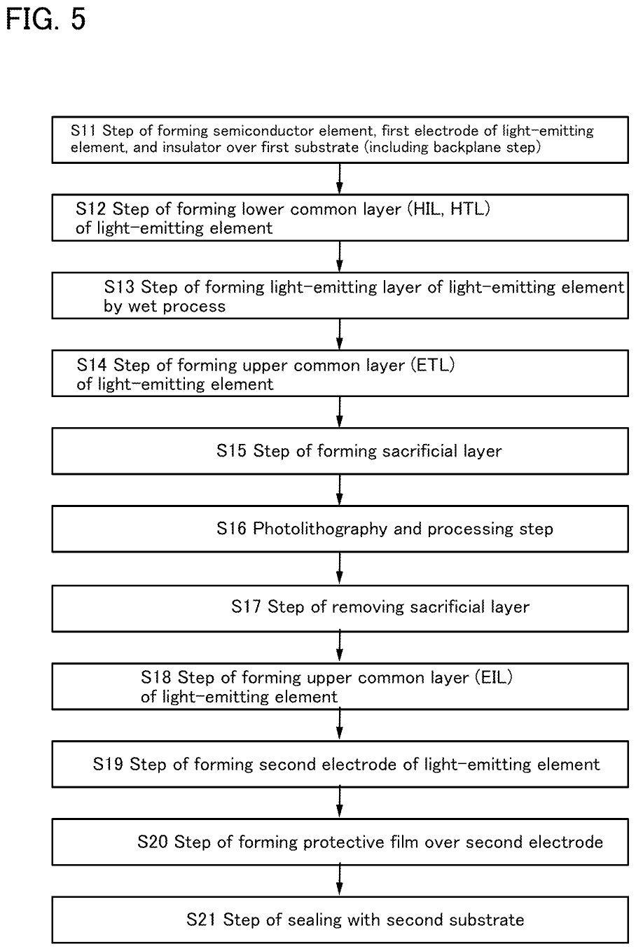

As shown in Step S11 in FIG. 5, a semiconductor element, the first electrode 102 of the light-emitting element, and the insulator 105 with the opening portion 104 are formed over the first substrate 100. Such Step S11 includes a formation step of the semiconductor element, i.e., a backplane step.

As shown in Step S12 in FIG. 5, a lower common layer of the light-emitting elements is formed. As the lower common layer, one or more selected from a hole-injection layer and a hole-transport layer can be used.

The common layer can be formed by a wet process. Examples of a wet process include an inkjet method and a spin coating method.

The common layer may be formed by an evaporation method. As an evaporation method, a vacuum evaporation method is preferable.

As shown in Step S13 in FIG. 5, light-emitting layers are formed by a wet process.

The light-emitting layers can be formed by a wet process. Examples of a wet process include an inkjet method and a spin coating method.

As shown in Step S14 in FIG. 5, an upper common layer of the light-emitting element is formed. One or more selected from an electron-injection layer and an electron-transport layer can be used as the upper common layer: for example, an electron-transport layer is formed.

The common layer can be formed by a wet process. Examples of a wet process include an inkjet method and a spin coating method.

The common layer may be formed by an evaporation method. As an evaporation method, a vacuum evaporation method is preferable.

As shown in Step S15 in FIG. 5, a sacrificial layer is formed.

As shown in Step S16 in FIG. 5, material layers are processed by a photolithography method or the like. Since the processing step is performed in the state where the sacrificial layer is provided, the material layers and the like are not removed, which is preferable. Note that a resist mask is necessary for the processing by a photolithography method or the like.

As shown in Step S17 in FIG. 5, the sacrificial layer is removed. At the same time, the resist mask is removed.

As shown in Step S18 in FIG. 5, an upper common layer of the light-emitting element is formed. One or more selected from an electron-injection layer and an electron-transport layer can be used as the upper common layer; for example, an electron-injection layer is formed.

As shown in Step S19 in FIG. 5, a second electrode of the light-emitting element is formed. The above is the steps described with reference to FIG. 4 and the like.

Next, a protective film is preferably formed over the second electrode as shown in Step S20 in FIG. 5. The protective film can be formed by a sputtering method or a plasma CVD method. The protective film preferably contain an inorganic material, and silicon oxide, silicon nitride, silicon oxynitride, or aluminum oxide can be used. A stacked structure in which layers of these materials are stacked may be used for the protective film.

Next, as shown in Step S21 in FIG. 5, sealing is performed with a second substrate. A solid sealing structure, a hollow sealing structure, or the like can be employed for the sealing. The solid sealing structure is a structure in which sealing is performed with an adhesive such as an organic resin. In the solid sealing structure, the second substrate can be omitted. The hollow sealing structure is a sealing structure in which the surrounded space is filled with an inert gas (nitrogen, argon, or the like).

The description in this embodiment can be used in combination with the other embodiments.

### Embodiment 3

In this embodiment, structure examples of a transistor that can be used in the display device of one embodiment of the present invention will be described. Specifically, the case of using a transistor containing silicon as a semiconductor where a channel is formed will be described. The semiconductor containing silicon is referred to as a silicon layer in some cases.

One embodiment of the present invention is a display device including a light-emitting element and a pixel circuit in a display portion. For example, when a display device includes three kinds of light-emitting elements emitting light of red (R), green (G), and blue (B), a full-color display device can be achieved. The three kinds of light-emitting elements emitting light of red (R), green (G), and blue (B) are sometimes referred to as a first light-emitting element, a second light-emitting element, and a third light-emitting element to be distinguished from each other.

Transistors containing silicon in their semiconductor layers where channels are formed are preferably used as all transistors included in the pixel circuit for driving the light-emitting element. As silicon, single crystal silicon, polycrystalline silicon, amorphous silicon, and the like can be given. In particular, transistors containing low-temperature polysilicon (LTPS) in their semiconductor layers (such transistors are referred to as LTPS transistors below) are preferably used. The LTPS transistors contain silicon that is crystallized in the temperature range in which the silicon can be formed over a glass substrate, and they have high field-effect mobility and favorable frequency characteristics.

With the use of transistors using silicon, such as LTPS transistors, a circuit required to be driven at a high frequency (e.g., a source driver circuit) can be formed on the same substrate as the display portion. Thus, external circuits mounted on the display device can be simplified, and costs of parts and mounting costs can be reduced.

It is preferable to use transistors including a metal oxide (hereinafter also referred to as an oxide semiconductor) in a semiconductor (such transistors are hereinafter also referred to as OS transistors) as at least one of the transistors included in the pixel circuit.

There is no particular limitation on the crystallinity of the oxide semiconductor, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or an oxide semiconductor having crystallinity is preferably used, in which case deterioration of the transistor characteristics can be inhibited.

The band gap of the oxide semiconductor is preferably greater than or equal to 2 eV, further preferably greater than or equal to 2.5 eV. With the use of a metal oxide having a wide bandgap in the oxide semiconductor, the off-state current of the OS transistor can be reduced.

A metal oxide contains preferably at least indium or zinc and further preferably indium and zinc. A metal oxide preferably contains indium, M (M is one or more kinds selected from gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin, and M is further preferably gallium. Hereinafter, a metal oxide containing indium, M, and zinc is referred to as an In-M-Zn oxide in some cases.

When a metal oxide is an In-M-Zn oxide, the atomic ratio of In is preferably higher than or equal to the atomic ratio of M in the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of +30% of an intended atomic ratio. By increasing the proportion of the number of indium atoms in the metal oxide, the on-state current, field-effect mobility, or the like of the OS transistor can be improved.

The case where Ga is used as M will be described. For example, in the case of describing an atomic ratio of In:Ga:Zn=4:2:3 or a composition in the vicinity thereof, the case is included in which with the atomic ratio of In being 4, the atomic ratio of Ga is greater than or equal to 1 and less than or equal to 3 and the atomic ratio of Zn is greater than or equal to 2 and less than or equal to 4. In the case of describing an atomic ratio of In:Ga:Zn=5:1:6 or a composition in the vicinity thereof, the case is included in which with the atomic ratio of In being 5, the atomic ratio of Ga is greater than 0.1 and less than or equal to 2 and the atomic ratio of Zn is greater than or equal to 5 and less than or equal to 7. In the case of describing an atomic ratio of In:Ga:Zn=1:1:1 or a composition in the vicinity thereof, the case is included in which with the atomic ratio of In being 1, the atomic ratio of Ga is greater than 0.1 and less than or equal to 2 and the atomic ratio of Zn is greater than 0.1 and less than or equal to 2.

The atomic ratio of In may be less than the atomic ratio of M in the In-M-Zn oxide. Examples of the atomic ratio of the metal elements in such an In-M-Zn oxide include In:M:Zn=1:3:2 or a composition in the neighborhood thereof, In:M:Zn=1:3:3 or a composition in the neighborhood thereof, and In:M:Zn=1:3:4 or a composition in the neighborhood thereof. By increasing the ratio of the number of M atoms in the metal oxide, the band gap of the In-M-Zn oxide is further increased; thus, the resistance to a negative bias stress test with light irradiation can be improved. Specifically, the amount of change in the threshold voltage or the amount of change in the shift voltage (Vsh) measured in a NBTIS (Negative Bias Temperature Illumination Stress) test of the OS transistor can be decreased. Note that the shift voltage (Vsh) is defined as Vg at which, in a drain current (Id)-gate voltage (Vg) curve of a transistor, the tangent at a point where the slope of the curve is the steepest intersects the straight line of Id=1 pA.

An OS transistor has extremely higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the OS transistor can be retained for a long period. Power consumption of the display device can be reduced with the use of such an OS transistor.

When an LTPS transistor is used as one or more of the plurality of transistors included in the pixel circuit and an OS transistor is used as the rest, a display device with low power consumption and high driving capability can be achieved. As a more favorable example, it is preferable to use an OS transistor as a transistor or the like functioning as a switch for controlling electrical continuity between wirings and an LTPS transistor as a transistor or the like for controlling a current.

For example, one of the plurality of transistors included in the pixel circuit functions as a transistor for controlling current flowing through the light-emitting element and is referred to as a driving transistor. One of a source and a drain of the driving transistor is electrically connected to the pixel electrode of the light-emitting element. An LTPS transistor is preferably used as the driving transistor. In this case, the amount of current flowing through the light-emitting element can be increased in the pixel circuit.

Another transistor included in the pixel circuit functions as a switch for controlling selection and non-selection of the pixel and is referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., 1 fps or less); thus, a clock signal or the like from a gate driver can be stopped in displaying a still image, leading to a reduction in power consumption.

More specific structure examples will be described below with reference to drawings.

### [Structure Example of Display Device]

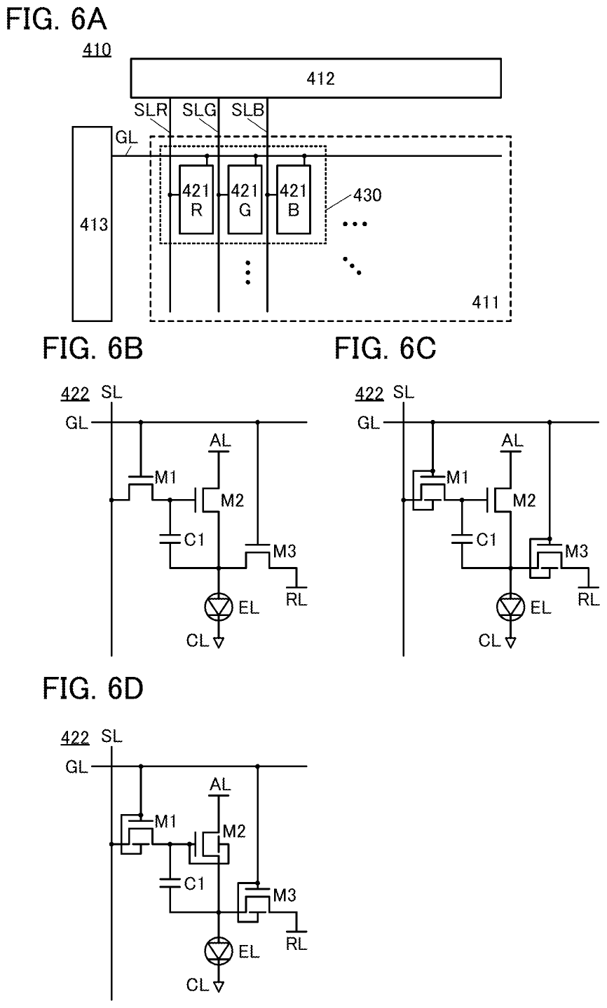

FIG. 6A illustrates a block diagram of a display device 410. The display device 410 includes a display portion 411, a driver circuit portion 412, a driver circuit portion 413, and the like. The driver circuit portion 412 includes a source driver, and a gate driver includes a driver circuit portion 413.

The display portion 411 includes a plurality of pixels 430 arranged in a matrix. The pixels 430 each include a subpixel 421R, a subpixel 421G, and a subpixel 421B. The subpixel 421R, the subpixel 421G, and the subpixel 421B each include a light-emitting element, and the light-emitting element functions as a display element.

The pixel 430 is electrically connected to a wiring GL, a wiring SLR, a wiring SLG, and a wiring SLB. The wiring SLR, the wiring SLG, and the wiring SLB are electrically connected to the driver circuit portion 412. The wiring GL is electrically connected to the driver circuit portion 413. The driver circuit portion 412 functions as a source driver (also referred to as a source line driver circuit), and the driver circuit portion 413 functions as a gate driver (also referred to as a gate line driver circuit). The wiring GL functions as a gate line, and the wiring SLR, the wiring SLG, and the wiring SLB function as source lines.

The subpixel 421R includes a light-emitting element emitting red light. The subpixel 421G includes a light-emitting element emitting green light. The subpixel 421B includes a light-emitting element emitting blue light. Thus, the display device 410 can perform full-color display. Note that the pixel 430 may include a subpixel including a light-emitting element emitting light of another color. For example, the pixel 430 may include, in addition to the three subpixels, a subpixel including a light-emitting element emitting white light, a subpixel including a light-emitting element emitting yellow light, or the like.

The wiring GL is electrically connected to the subpixel 421R, the subpixel 421G, and the subpixel 421B arranged in the row direction (the extending direction of the wiring GL). The wiring SLR, the wiring SLG, and the wiring SLB are electrically connected to the subpixels 421R, the subpixels 421G, and the subpixels 421B (the subpixels arranged in a column direction are not illustrated) arranged in a column direction (an extending direction of the wiring SLR and the like), respectively.

### [Structure Example of Pixel Circuit]

FIG. 6B illustrates an example of a circuit diagram of a pixel circuit 422 that can be used as the subpixel 421R, the subpixel 421G, and the subpixel 421B. The pixel circuit 422 includes a transistor M1, a transistor M2, a transistor M3, a capacitor C1, and a light-emitting element EL. The pixel circuit 422 includes the wiring GL and a wiring SL. The wiring SL corresponds to any of the wiring SLR, the wiring SLG, and the wiring SLB illustrated in FIG. 6A.

A gate of the transistor M1 is electrically connected to the wiring GL, one of a source and a drain of the transistor M1 is electrically connected to the wiring SL, and the other of the source and the drain of the transistor M1 is electrically connected to one electrode of the capacitor C1 and a gate of the transistor M2. One of a source and a drain of the transistor M2 is electrically connected to a wiring AL, and the other of the source and the drain of the transistor M2 is electrically connected to one electrode of the light-emitting element EL, the other electrode of the capacitor C1, and one of a source and a drain of the transistor M3. A first electrode corresponds to the one electrode of the light-emitting element EL. A gate of the transistor M3 is electrically connected to the wiring GL, and the other of the source and the drain of the transistor M3 is electrically connected to a wiring RL. The other electrode of the light-emitting element EL is electrically connected to a wiring CL. A second electrode corresponds to the one electrode of the light-emitting element EL.

A data potential D is supplied to the wiring SL. A selection signal is supplied to the wiring GL. The selection signal includes a potential for turning on a transistor whose gate is electrically connected to the wiring GL and a potential for turning off the transistor.

A reset potential is supplied to the wiring RL. An anode potential is supplied to the wiring AL. A cathode potential is supplied to the wiring CL. In the pixel circuit 422, the anode potential is higher than the cathode potential. The reset potential supplied to the wiring RL can be set such that a potential difference between the reset potential and the cathode potential is lower than the threshold voltage of the light-emitting element EL. The reset potential can be a potential higher than the cathode potential, a potential equal to the cathode potential, or a potential lower than the cathode potential.

The transistor M1 and the transistor M3 function as switches. The transistor functioning as a switch is referred to as a selection transistor in some cases. For example, the transistor M2 functions as a transistor for controlling current flowing through the light-emitting element EL. The transistor for controlling current flowing through the light-emitting element EL is referred to as a driving transistor in some cases. For example, it can be regarded that the transistor M1 functions as a selection transistor and the transistor M2 functions as a driving transistor.

Here, it is preferable to use LTPS transistors as all of the transistor M1 to the transistor M3. Alternatively, it is preferable to use OS transistors as the transistor M1 and the transistor M3 and to use an LTPS transistor as the transistor M2.

Alternatively, OS transistors may be used as all the transistor M1 to the transistor M3. In that case, an LTPS transistor can be used as at least one of a plurality of transistors included in the driver circuit portion 412 and a plurality of transistors included in the driver circuit portion 413, and OS transistors can be used as the other transistors. For example, OS transistors can be used as the transistors provided in the display portion 411, and LTPS transistors can be used as the transistors provided in the driver circuit portion 412 and the driver circuit portion 413.

As already described above, the OS transistor is a transistor including an oxide semiconductor in a semiconductor layer in which a channel is formed can be used. The oxide semiconductor preferably contains indium, M (M is one or more selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin. It is particularly preferable to use an oxide containing indium, gallium, and zinc (also referred to as IGZO) for the semiconductor of the OS transistor. Alternatively, it is preferable to use an oxide containing indium, tin, and zinc for the semiconductor of the OS transistor. Further alternatively, it is preferable to use an oxide containing indium, gallium, tin, and zinc for the semiconductor of the OS transistor.

An OS transistor using an oxide semiconductor having a wider band gap and a lower carrier density than silicon can achieve an extremely low off-state current. Thus, such a low off-state current enables long-term retention of charge accumulated in a capacitor that is connected in series with the OS transistor. Hence, it is particularly preferable to use OS transistors including an oxide semiconductor as the transistor M1 and the transistor M3 connected in series to the capacitor C1. The use of the OS transistor as each of the transistor M1 and the transistor M3 can prevent leakage of charge retained in the capacitor C1 through the transistor M1 or the transistor M3. Furthermore, since charge held in the capacitor C1 can be held for a long period, a still image can be displayed for a long period without rewriting data in the pixel 421.

Note that although the transistor is illustrated as an n-channel transistor in FIG. 6B, a p-channel transistor can also be used.

The transistors included in the pixel circuit 422 are preferably formed to be arranged over one substrate.

A transistor including a pair of gates overlapping with a semiconductor layer therebetween can be used as the transistor included in the pixel circuit 422. The transistor included in the pixel circuit 422 is an LTPS transistor or an OS transistor.

In the transistor including a pair of gates, the same potential is supplied to the pair of gates electrically connected to each other, whereby the on-state current of the transistor can be increased and the saturation characteristics can be improved. A potential for controlling the threshold voltage of the transistor may be supplied to one of the pair of gates. Furthermore, when a constant potential is supplied to one of the pair of gates, the stability of the electrical characteristics of the transistor can be improved. For example, one of the gates of the transistor may be electrically connected to a wiring to which a constant potential is supplied or may be electrically connected to a source or a drain of the transistor.

The pixel circuit 422 illustrated in FIG. 6C is an example where a transistor including a pair of gates is used as each of the transistor M1 and the transistor M3. The pair of gates are electrically connected to each other in each of the transistor M1 and the transistor M3. Such a structure makes it possible to shorten the period in which data is written to the pixel circuit 422.

The pixel circuit 422 illustrated in FIG. 6D is an example where a transistor including a pair of gates is used as the transistor M2 in addition to the transistor M1 and the transistor M3. The pair of gates of the transistor M2 are electrically connected to each other. When such a transistor is used as the transistor M2, the saturation characteristics are improved, whereby emission luminance of the light-emitting element EL can be controlled easily and the display quality can be increased.

### [Cross-Sectional Structure Example of Display Device]

Cross-sectional structure examples of a transistor that can be used in the above display device will be described below.

### Structure Example 1

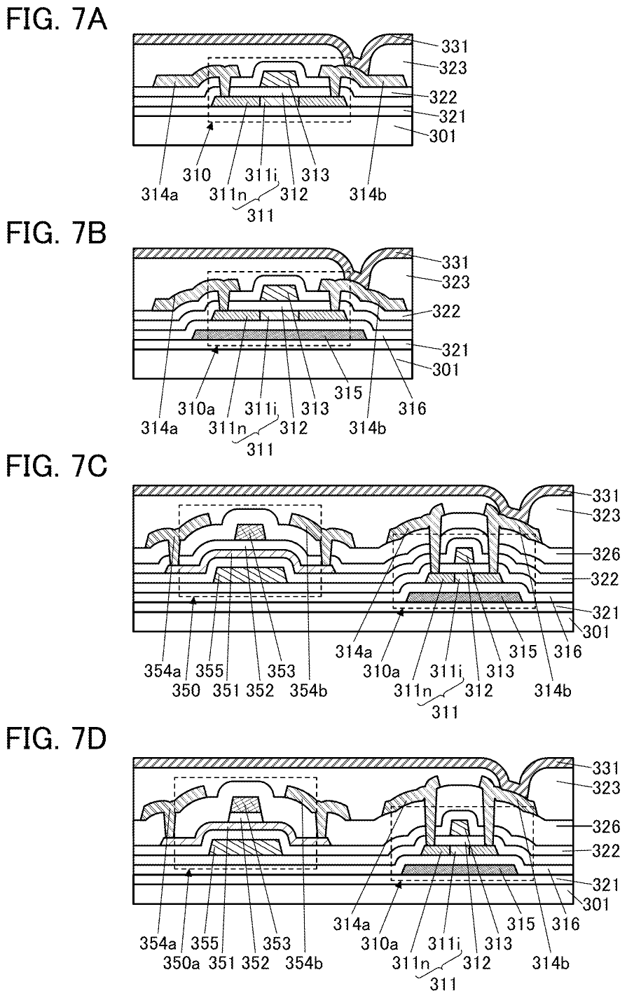

FIG. 7A is a cross-sectional view including a transistor 310.

The transistor 310 is an LTPS transistor provided over a substrate 301 and containing polycrystalline silicon in its semiconductor layer. For example, the transistor 310 corresponds to the transistor M2 included in the pixel circuit 422 in FIG. 6B to FIG. 6D. In other words, FIG. 7A illustrates an example in which one of a source and a drain of the transistor 310 is electrically connected to a conductive layer 331 of the light-emitting element. The conductive layer 331 is referred to as a pixel electrode or a first electrode of the light-emitting element in some cases.

The transistor 310 includes a semiconductor layer 311, an insulating layer 312, a conductive layer 313, and the like. The semiconductor layer 311 includes a channel formation region 311i and low-resistance regions 311n. At least the channel formation region 311i contains silicon, preferably contains polycrystalline silicon. Part of the insulating layer 312 functions as a gate insulating layer. Part of the conductive layer 313 functions as a gate electrode. The semiconductor layer 311 overlapping with the conductive layer 313 is the channel formation region 311i. The conductive layer 313 overlapping with the semiconductor layer 311 functions as the gate electrode.

Note that the semiconductor layer 311 can include a metal oxide exhibiting semiconductor characteristics (also referred to as an oxide semiconductor) at least in the channel formation region. That is, an OS transistor may be used as the transistor 310.

The low-resistance region 311n is a region containing an impurity element. For example, in the case where the transistor 310 is an n-channel transistor, phosphorus, arsenic, or the like is added to the low-resistance regions 311n. Meanwhile, in the case where the transistor 310 is a p-channel transistor, boron, aluminum, or the like is added to the low-resistance regions 311n. In addition, in order to control the threshold voltage of the transistor 310, the above-described impurity may be added to the channel formation region 311i.

An insulating layer 321 is provided over the substrate 301. The semiconductor layer 311 is provided over the insulating layer 321. The insulating layer 312 is provided to cover the semiconductor layer 311 and the insulating layer 321. The conductive layer 313 is provided at a position that is over the insulating layer 312 and overlaps with the semiconductor layer 311.

An insulating layer 322 is provided to cover the conductive layer 313 and the insulating layer 312. A conductive layer 314a and a conductive layer 314b are provided over the insulating layer 322. The conductive layer 314a and the conductive layer 314b are electrically connected to the low-resistance regions 311n in opening portions provided in the insulating layer 322 and the insulating layer 312. Part of the conductive layer 314a functions as one of a source electrode and a drain electrode and part of the conductive layer 314b functions as the other of the source electrode and the drain electrode. An insulating layer 323 is provided to cover the conductive layer 314a, the conductive layer 314b, and the insulating layer 322.

The conductive layer 331 functioning as a pixel electrode is provided over the insulating layer 323. The conductive layer 331 is provided over the insulating layer 323 and is electrically connected to the conductive layer 354b in an opening provided in the insulating layer 323. The conductive layer 331 functions as a reflective electrode, and thus preferably has a top surface with a high reflectance with respect to visible light. Although not illustrated here, a functional layer and a common electrode can be stacked over the conductive layer 331, and a light-emitting layer and the like included in the functional layer is preferably formed by a wet process.

### Structure Example 2

FIG. 7B illustrates a transistor 310a including a pair of gate electrodes. The transistor 310a illustrated in FIG. 7B is different from that in FIG. 7A mainly in including a conductive layer 315 and an insulating layer 316. Note that the semiconductor layer 311 can include a metal oxide exhibiting semiconductor characteristics (also referred to as an oxide semiconductor) at least in the channel formation region, and thus an OS transistor may be used as the transistor 310a.

The conductive layer 315 is provided over the insulating layer 321. The insulating layer 316 is provided to cover the conductive layer 315 and the insulating layer 321. The semiconductor layer 311 is provided such that at least the channel formation region 311i overlaps with the conductive layer 315 with the insulating layer 316 therebetween.

In the transistor 310a illustrated in FIG. 7B, part of the conductive layer 313 functions as a first gate electrode, and part of the conductive layer 315 functions as a second gate electrode. At this time, part of the insulating layer 312 functions as a first gate insulating layer, and part of the insulating layer 316 functions as a second gate insulating layer.

Here, as illustrated in FIG. 6C or FIG. 6D, to electrically connect the first gate electrode to the second gate electrode, the conductive layer 313 is electrically connected to the conductive layer 315 through an opening portion provided in the insulating layer 312 and the insulating layer 316 in a region not illustrated. To electrically connect the second gate electrode to a source or a drain, the conductive layer 315 is electrically connected to the conductive layer 314a or the conductive layer 314b through an opening portion provided in the insulating layer 322, the insulating layer 312, and the insulating layer 316 in a region not illustrated.

In the case where LTPS transistors are used as all of the transistors included in the pixel circuit 422 in FIG. 6B to FIG. 6D, the transistor 310 illustrated in FIG. 7A as an example or the transistor 310a illustrated in FIG. 7B as an example can be used. In this case, the transistors 310a may be used as all of the transistors included in the pixel circuit, the transistors 310 may be used as all of the transistors, or the transistors 310a and the transistors 310 may be used in combination.

### Structure Example 3

Described below is an example of a structure including both a transistor containing silicon in its semiconductor layer and an OS transistor containing a metal oxide in its semiconductor layer. A semiconductor layer containing a metal oxide is referred to as an oxide semiconductor layer in some cases.

FIG. 7C is a schematic cross-sectional view including the transistor 310a and a transistor 350. Note that FIG. 7C illustrates an example where the transistor 310a is used; however, the transistor 310 may be included instead of the transistor 310a, and the transistor 310 and the transistor 350 may be included as a modification example of FIG. 7C. Alternatively, the transistor 310 may be included instead of the transistor 350, and as a modification example of FIG. 7C, the transistor 310 and the transistor 310a may be included.

The structure example 1 described above can be referred to for the transistor 310, and the structure example 2 described above can be referred to for the transistor 310a. An LTPS transistor can be used as the transistor 310a, and the transistor 310a can be used as one or both selected from the transistor M2 and the transistor M3 in the pixel circuit 422 in FIG. 6B to FIG. 6D.

An OS transistor containing a metal oxide in its semiconductor layer can be used as the transistor 350, and the transistor 350 can be used as the transistor M1 in the pixel circuit 422 in FIG. 6B to FIG. 6D. That is, FIG. 7C illustrates an example in which one of a source and a drain of the transistor 310a is electrically connected to the conductive layer 331.

Moreover, FIG. 7C illustrates an example in which the transistor 350 includes a pair of gates.

The transistor 350 includes a conductive layer 355, the insulating layer 322, a semiconductor layer 351, an insulating layer 352, a conductive layer 353, and the like. Part of the conductive layer 353 functions as a first gate of the transistor 350, and part of the conductive layer 355 functions as a second gate of the transistor 350. Part of the insulating layer 352 functions as a first gate insulating layer of the transistor 350, and part of the insulating layer 322 functions as a second gate insulating layer of the transistor 350.

The conductive layer 355 is provided over the insulating layer 312. The insulating layer 322 is provided to cover the conductive layer 355. The semiconductor layer 351 is provided over the insulating layer 322. The insulating layer 352 is provided to cover the semiconductor layer 351 and the insulating layer 322. The conductive layer 353 is provided over the insulating layer 352 and includes a region overlapping with the semiconductor layer 351 and the conductive layer 355.

The insulating layer 326 is provided to cover the insulating layer 352 and the conductive layer 353. A conductive layer 354a and a conductive layer 354b are provided over the insulating layer 326. The conductive layer 354a and the conductive layer 354b are electrically connected to the semiconductor layer 351 in opening portions provided in the insulating layer 326 and the insulating layer 352. Part of the conductive layer 354a functions as one of a source electrode and a drain electrode and part of the conductive layer 354b functions as the other of the source electrode and the drain electrode. The conductive layer 354a and the conductive layer 354b are preferably formed in the same step as the conductive layer 314a and the conductive layer 314b. The insulating layer 323 is provided to cover the conductive layer 354a, the conductive layer 354b, and the insulating layer 326.

Here, the conductive layer 314a and the conductive layer 314b electrically connected to the transistor 310a are preferably formed by processing the same conductive film as the conductive layer 354a and the conductive layer 354b. FIG. 7C illustrates a structure where the conductive layer 314a, the conductive layer 314b, the conductive layer 354a, and the conductive layer 354b are formed on the same plane (i.e., in contact with the top surface of the insulating layer 326) and contain the same metal element. In this case, the conductive layer 314a and the conductive layer 314b are electrically connected to the low-resistance regions 311n through openings provided in the insulating layer 326, the insulating layer 352, the insulating layer 322, and the insulating layer 312. This is preferable because the manufacturing process can be simplified.

Moreover, the conductive layer 313 functioning as the first gate electrode of the transistor 310a and the conductive layer 355 functioning as the second gate electrode of the transistor 350 are preferably formed by processing the same conductive film. FIG. 7C illustrates a structure where the conductive layer 313 and the conductive layer 355 are formed on the same plane (i.e., in contact with the top surface of the insulating layer 312) and contain the same metal element. This is preferable because the manufacturing process can be simplified.

In FIG. 7C, the insulating layer 352 functioning as the first gate insulating layer of the transistor 350 covers an end portion of the semiconductor layer 351: however, the insulating layer 352 may be processed to have substantially the same top surface shape as that of the conductive layer 353 as in the transistor 350a illustrated in FIG. 7D.

Note that in this specification and the like, the expression “top surface shapes are substantially aligned with each other” means that at least outlines of stacked layers partly overlap with each other. For example, the case of processing the upper layer and the lower layer with the use of the same mask pattern or mask patterns that are partly the same is included. However, in some cases, the outlines do not completely overlap with each other and the upper layer is positioned on an inner side of the lower layer or the upper layer is positioned on an outer side of the lower layer: such a case is also represented by the expression “top surface shapes are substantially aligned with each other”.

Although the example in which the transistor 310a corresponds to the transistor M2 and is electrically connected to the pixel electrode is shown here, one embodiment of the present invention is not limited thereto. For example, a structure where the transistor 350 or the transistor 350a corresponds to the transistor M2 may be employed. In this case, the transistor 310a corresponds to one or both selected from the transistor M1 and the transistor M3, or another transistor.

At least part of the structure examples, the drawings corresponding thereto, and the like described in this embodiment as an example can be combined with the other structure examples, the other drawings, and the like as appropriate.

At least part of this embodiment can be implemented in combination with the other embodiments described in this specification as appropriate.

### Embodiment 4

In this embodiment, structures of a data processing device of one embodiment of the present invention will be described with reference to the drawings.

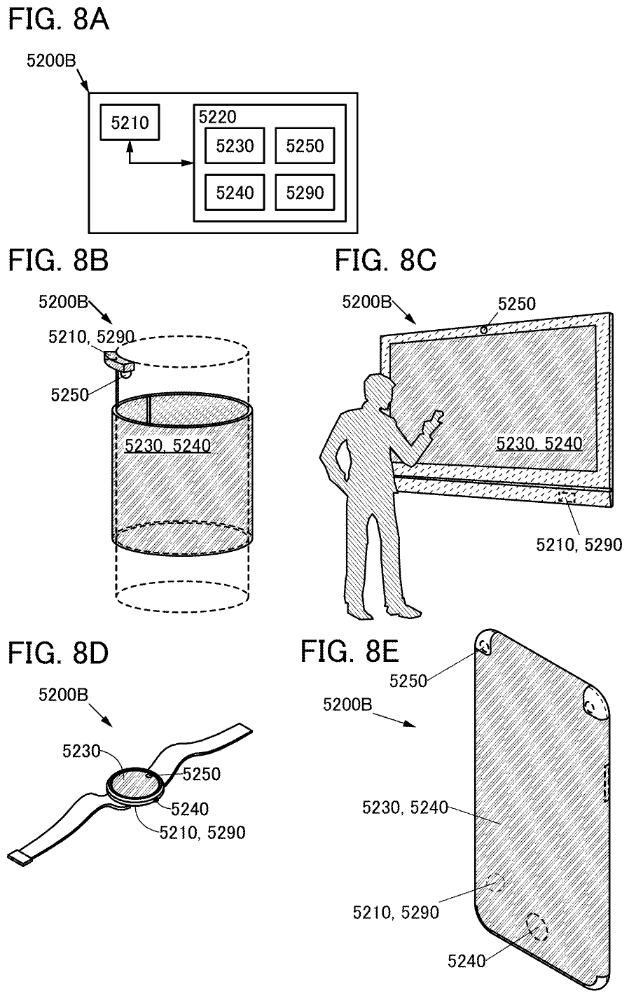

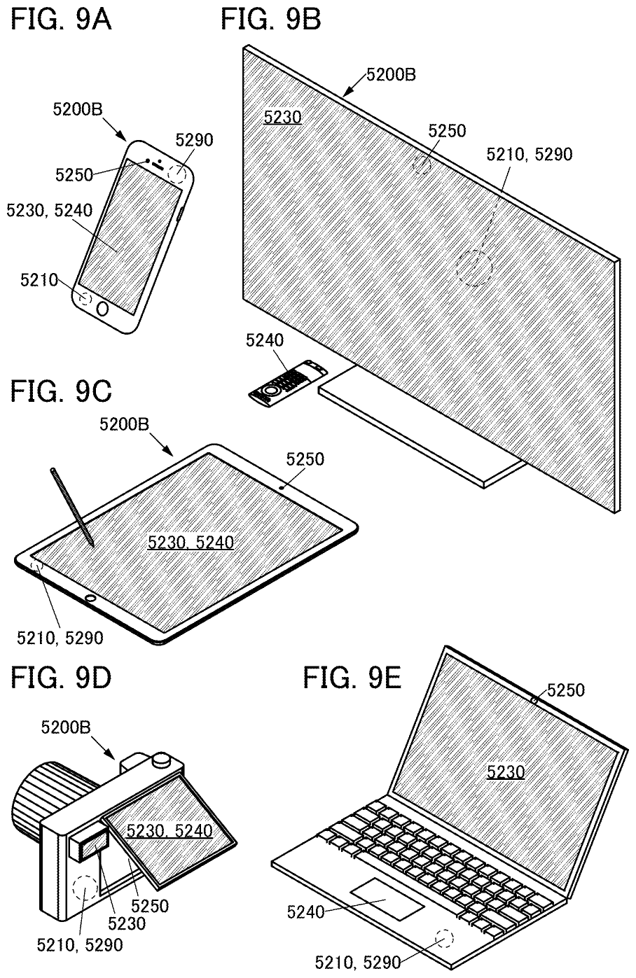

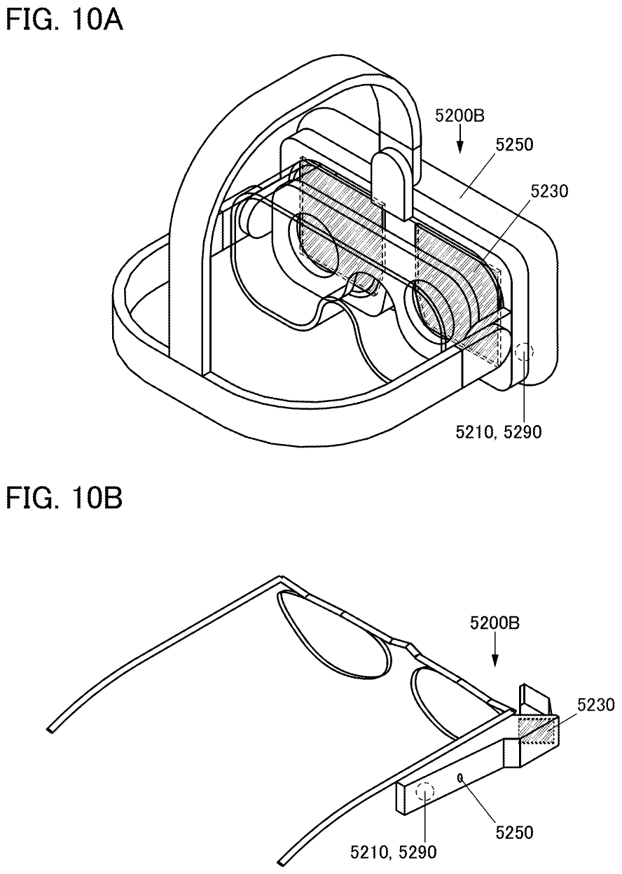

FIG. 8 to FIG. 10 are diagrams illustrating structures of the data processing device of one embodiment of the present invention. FIG. 8A is a block diagram of the data processing device, and FIG. 8B to FIG. 8E are perspective views illustrating structures of the data processing device. FIG. 9A to FIG. 9E are perspective views illustrating structures of the data processing device. FIG. 10A and FIG. 10B are perspective views illustrating structures of the data processing device.

### <Data Processing Device>

A data processing device 5200B described in this embodiment includes an arithmetic device 5210 and an input/output device 5220 (see FIG. 8A).

The arithmetic device 5210 has a function of being supplied with operation information and a function of supplying image information on the basis of the operation information.

The input/output device 5220 includes a display portion 5230, an input portion 5240, a sensing portion 5250, and a communication portion 5290 and has a function of supplying operation information and a function of being supplied with image information. The input/output device 5220 also has a function of supplying sensing information, a function of supplying communication information, and a function of being supplied with communication information.

The input portion 5240 has a function of supplying operation information. For example, the input portion 5240 supplies operation information on the basis of operation by a user of the data processing device 5200B.

Specifically, a keyboard, a hardware button, a pointing device, a touch sensor, an illuminance sensor, an imaging device, an audio input device, an eye-gaze input device, an attitude detection device, or the like can be used as the input portion 5240.

The display portion 5230 includes a display device and has a function of displaying image information. For example, the display device described in Embodiment 1 can be used for the display portion 5230.

The sensing portion 5250 has a function of supplying sensing information. For example, the sensing portion 5250 has a function of sensing a surrounding environment where the data processing device is used and supplying sensing information.

Specifically, an illuminance sensor, an imaging device, an attitude detection device, a pressure sensor, a human motion sensor, or the like can be used as the sensing portion 5250.

The communication portion 5290 has a function of being supplied with communication information and a function of supplying communication information. For example, the communication portion 5290 has a function of being connected to another electronic device or a communication network through wireless communication or wired communication. Specifically, the communication portion 5290 has a function of wireless local area network communication, telephone communication, near field communication, or the like.

### <<Structure Example 1 of Data Processing Device>>

For example, the display portion 5230 can have an outer shape along a cylindrical column or the like (see FIG. 8B). In addition, the data processing device has a function of changing its display method in accordance with the illuminance of a usage environment. Furthermore, the data processing device has a function of changing displayed content in response to sensed existence of a person. This allows the data processing device to be provided on a column of a building, for example. The data processing device can display advertising, guidance, or the like. The data processing device can be used for digital signage or the like.

### <<Structure Example 2 of Data Processing Device>>

For example, the data processing device has a function of generating image information on the basis of the path of a pointer used by a user (see FIG. 8C). Specifically, the display device with a diagonal size of 20 inches or longer, preferably 40 inches or longer, further preferably 55 inches or longer can be used. Alternatively, a plurality of display devices can be arranged and used as one display region. Alternatively, a plurality of display devices can be arranged and used as a multiscreen. Thus, the data processing device can be used for an electronic blackboard, an electronic bulletin board, digital signage, or the like.

### <<Structure Example 3 of Data Processing Device>>

The data processing device can receive information from another device, and the information can be displayed on the display portion 5230 (see FIG. 8D). Several options can be displayed. The user can choose some from the options and send a reply to a transmitter of the information. For example, the data processing device has a function of changing its display method in accordance with the illuminance of a usage environment. Thus, for example, the power consumption of a smartwatch (registered trademark) can be reduced. Alternatively, for example, a smartwatch can display an image so as to be suitably used even in an environment under strong external light, e.g., outdoors in fine weather.

### <<Structure Example 4 of Data Processing Device>>

For example, the display portion 5230 has a surface gently curved along a side surface of a housing (see FIG. 8E). The display portion 5230 includes a display device, and the display device has a function of performing display on the front surface, the side surfaces, the top surface, and the rear surface, for example. Thus, for example, a mobile phone can display information not only on its front surface but also on its side surfaces, its top surface, and its rear surface.

### <<Structure Example 5 of Data Processing Device>>

For example, the data processing device can receive information via the Internet and display the information on the display portion 5230 (see FIG. 9A). A created message can be checked on the display portion 5230. The created message can be sent to another device. The data processing device has a function of changing its display method in accordance with the illuminance of a usage environment, for example. Thus, the power consumption of a smartphone can be reduced. Alternatively, for example, a smartphone can display an image so as to be suitably used even in an environment under strong external light, e.g., outdoors in fine weather.

### <<Structure Example 6 of Data Processing Device>>

A remote controller can be used as the input portion 5240 (see FIG. 9B). For example, the data processing device can receive information from a broadcast station or via the Internet and display the information on the display portion 5230. An image of a user can be captured using the sensing portion 5250. The image of the user can be transmitted. The data processing device can acquire a viewing history of the user and provide it to a cloud service. The data processing device can acquire recommendation information from a cloud service and display the information on the display portion 5230. A program or a moving image can be displayed on the basis of the recommendation information. For example, the data processing device has a function of changing its display method in accordance with the illuminance of a usage environment. Accordingly, for example, a television system can display an image to be suitably used even when irradiated with strong external light that enters a room in fine weather.

### <<Structure Example 7 of Data Processing Device>>

For example, the data processing device can receive educational materials via the Internet and display them on the display portion 5230 (see FIG. 9C). An assignment can be input with the input portion 5240 and sent via the Internet. A corrected assignment or the evaluation of the assignment can be obtained from a cloud service and displayed on the display portion 5230. Suitable educational materials can be selected on the basis of the evaluation and displayed.

For example, the display portion 5230 can perform display using an image signal received from another data processing device. When the data processing device is placed on a stand or the like, the display portion 5230 can be used as a sub-display. Thus, for example, a tablet computer can display an image to be suitably used even in an environment under strong external light, e.g., outdoors in fine weather.

### <<Structure Example 8 of Data Processing Device>>

The data processing device includes, for example, a plurality of display portions 5230 (see FIG. 9D). For example, the display portion 5230 can display an image that the sensing portion 5250 is capturing. A captured image can be displayed on the sensing portion. A captured image can be decorated using the input portion 5240. A message can be attached to a captured image. A captured image can be transmitted via the Internet. The data processing device has a function of changing its shooting conditions in accordance with the illuminance of a usage environment. Accordingly, for example, a digital camera can display a subject in such a manner that an image is favorably viewed even in an environment under strong external light, e.g., outdoors in fine weather.

### <<Structure Example 9 of Data Processing Device>>

For example, the data processing device of this embodiment is used as a master and another data processing device is used as a slave, whereby the other data processing device can be controlled (see FIG. 9E). As another example, part of image data can be displayed on the display portion 5230 and another part of the image data can be displayed on a display portion of another data processing device. Image signals can be supplied. With the communication portion 5290, information to be written can be obtained from an input portion of another data processing device. Thus, a large display region can be utilized by using a portable personal computer, for example.

### <<Structure Example 10 of Data Processing Device>>

The data processing device includes, for example, the sensing portion 5250 that senses an acceleration or a direction (see FIG. 10A). The sensing portion 5250 can supply information on the position of the user or the direction in which the user faces. The data processing device can generate image information for the right eye and image information for the left eye in accordance with the position of the user or the direction in which the user faces. The display portion 5230 includes a display region for the right eye and a display region for the left eye. Thus, a virtual reality image that gives the user a sense of immersion can be displayed on a goggles-type data processing device, for example.

### <<Structure Example 11 of Data Processing Device>>

The data processing device includes, for example, an imaging device and the sensing portion 5250 that senses an acceleration or a direction (see FIG. 10B). The sensing portion 5250 can supply information on the position of the user or the direction in which the user faces. The data processing device can generate image information in accordance with the position of the user or the direction in which the user faces. Accordingly, the information can be shown together with a real-world scene, for example. An augmented reality image can be displayed on a glasses-type data processing device.

Note that this embodiment can be combined with any of the other embodiments described in this specification as appropriate.

### REFERENCE NUMERALS

AL: wiring, CL: wiring, GL: wiring, RL: wiring, SL: wiring, SLB: wiring, SLG: wiring, SLR: wiring, 11: hole-injection layer, 12: hole-transport layer, 13a: light-emitting layer, 13b: light-emitting layer, 13c: light-emitting layer, 13: light-emitting layer, 14: electron-transport layer, 15; electron-injection layer, 16: charge-generation layer, 17: hole-transport region, 18: electron-transport region, 22: electron-relay layer, 23: p-type layer, 24: electron-injection buffer layer, 100; first substrate, 102: first electrode, 103a: first light-emitting unit, 103b: second light-emitting unit, 103: light-emitting unit, 104: opening portion, 105: insulator, 109: droplet, 110: nozzle, 113; material layer, 120: nozzle, 121: droplet, 122: material layer, 123: material layer, 126a: first electron-transport layer, 130: nozzle, 131: droplet, 132: material layer, 133: material layer, 136a: second electron-transport layer, 140: nozzle, 141: droplet, 142: material layer, 143: material layer, 146a: third electron-transport layer, 150: sacrificial layer, 160a: electron-transport layer, 160b: electron-injection layer, 160: layer, 161: second electrode, 301: substrate, 310a: transistor, 310: transistor, 311i: channel formation region, 311n: low-resistance region, 311: semiconductor layer, 312: insulating layer, 313: conductive layer, 314a: conductive layer, 314b: conductive layer, 315: conductive layer, 316: insulating layer, 321: insulating layer, 322: insulating layer, 323: insulating layer, 326: insulating layer, 331: conductive layer, 350a: transistor, 350: transistor, 351: semiconductor layer, 352: insulating layer, 353: conductive layer, 354a: conductive layer, 354b: conductive layer, 355: conductive layer, 410: display device, 411: display portion, 412: driver circuit portion, 413: driver circuit portion, 421B: subpixel, 421G: subpixel, 421R: subpixel, 421: pixel, 422: pixel circuit, 430: pixel, 5200B: data processing device, 5210: arithmetic device, 5220; input/output device, 5230: display portion, 5240: input portion, 5250: sensing portion, 5290: communication portion

1. A display device comprising:
a light-emitting element comprising a first electrode, an organic compound layer, and a second electrode;
a first transistor electrically connected to the first electrode;
a second transistor electrically connected to a gate of the first transistor; and
an insulator that covers an end portion of the first electrode,
wherein the first transistor comprises silicon in a channel formation region,
wherein the second transistor comprises an oxide semiconductor in a channel formation region,
wherein the insulator comprises an opening portion in a region overlapping with the first electrode, and
wherein an end portion of the organic compound layer is positioned in the opening portion of the insulator.

2. A display device comprising:
a light-emitting element comprising a first electrode, an organic compound layer, and a second electrode;
a first transistor electrically connected to the first electrode;
a second transistor electrically connected to a gate of the first transistor; and
an insulator that covers an end portion of the first electrode,
wherein the first transistor comprises silicon in a channel formation region,
wherein the second transistor comprises an oxide semiconductor in a channel formation region,
wherein the insulator comprises an opening portion in a region overlapping with the first electrode, and
wherein an end portion of the organic compound layer does not overlap with a top surface of the insulator.

3. A display device comprising:
a light-emitting element comprising a first electrode, an organic compound layer, and a second electrode;
a first transistor electrically connected to the first electrode;
a second transistor electrically connected to a gate of the first transistor; and
an insulator that covers an end portion of the first electrode,
wherein the first transistor comprises silicon in a channel formation region,
wherein the second transistor comprises an oxide semiconductor in a channel formation region,
wherein the insulator comprises an opening portion in a region overlapping with the first electrode,
wherein an end portion of the organic compound layer is positioned in the opening portion of the insulator, and
wherein thickness of the organic compound layer is larger in a neighboring region of the insulator than that in a center region of the opening portion of the insulator.

4. A display device comprising:
a light-emitting element comprising a first electrode, an organic compound layer, and a second electrode;
a first transistor electrically connected to the first electrode;
a second transistor electrically connected to a gate of the first transistor; and
an insulator that covers an end portion of the first electrode,
wherein the first transistor comprises silicon in a channel formation region,
wherein the second transistor comprises an oxide semiconductor in a channel formation region,
wherein the insulator comprises an opening portion in a region overlapping with the first electrode,
wherein an end portion of the organic compound layer does not overlap with a top surface of the insulator, and
wherein thickness of the organic compound layer is larger in a neighboring region of the insulator than that in a center region of the opening portion of the insulator.

5. The display device according to claim 1,
wherein the organic compound layer is one or both selected from a hole-injection layer and a hole-transport layer.

6. The display device according to claim 1,
wherein the oxide semiconductor comprises indium, gallium, and zinc.

7. The display device according to claim 1,
wherein the channel formation region of the first transistor comprises polycrystalline silicon.

8. A manufacturing method of a display device, comprising the steps of:
forming, over a substrate, a first transistor comprising silicon in a channel formation region and a second transistor comprising an oxide semiconductor in a channel formation region;
forming a first electrode of a first light-emitting element electrically connected to the first transistor;
forming an insulator comprising a first opening portion and a second opening portion;
forming, by a wet process, a first material layer comprising an organic compound in the first opening portion and a second material layer comprising an organic compound in the second opening portion;
selectively forming a first resist mask and a second resist mask over the first material layer and the second material layer, respectively; and
processing the first material layer using the first resist mask to form a third material layer so as not to overlap with a top surface of the insulator, and processing the second material layer using the second resist mask to form a fourth material layer so as not to overlap with a top surface of the insulator,
wherein the first opening portion overlaps with the first electrode,
wherein the first light-emitting element includes the third material layer, and
wherein a second light-emitting element includes the fourth material layer.

9. A manufacturing method of a display device, comprising the steps of:
forming, over a substrate, a first transistor comprising silicon in a channel formation region and a second transistor comprising an oxide semiconductor in a channel formation region;
forming a first electrode of a first light-emitting element electrically connected to the first transistor;
forming an insulator comprising a first opening portion and a second opening portion;
forming, by a wet process, a first material layer comprising a light-emitting material in the first opening portion and a second material layer comprising a light-emitting material in the second opening portion;
selectively forming a first resist mask and a second resist mask over the first material layer and the second material layer, respectively; and
processing the first material layer using the first resist mask to form a third material layer so as not to overlap with a top surface of the insulator, and processing the second material layer using the second resist mask to form a fourth material layer so as not to overlap with a top surface of the insulator,
wherein the first opening portion overlaps with the first electrode,
wherein the first light-emitting element includes the third material layer, and
wherein a second light-emitting element includes the fourth material layer.

10. The manufacturing method of a display device according to claim 8,
wherein an inkjet method or a spin coating method is used as the wet process.

11. The manufacturing method of a display device according to claim 8, further comprising the step of:
forming a sacrificial layer below the first resist mask and the second resist mask.

12. The display device according to claim 2,
wherein the organic compound layer is one or both selected from a hole-injection layer and a hole-transport layer.

13. The display device according to claim 2,
wherein the oxide semiconductor comprises indium, gallium, and zinc.

14. The display device according to claim 2,
wherein the channel formation region of the first transistor comprises polycrystalline silicon.

15. The display device according to claim 3,
wherein the organic compound layer is one or both selected from a hole-injection layer and a hole-transport layer.

16. The display device according to claim 3,
wherein the oxide semiconductor comprises indium, gallium, and zinc.

17. The display device according to claim 3,
wherein the channel formation region of the first transistor comprises polycrystalline silicon.

18. The display device according to claim 4,
wherein the organic compound layer is one or both selected from a hole-injection layer and a hole-transport layer.

19. The display device according to claim 4,
wherein the oxide semiconductor comprises indium, gallium, and zinc.

20. The display device according to claim 4,
wherein the channel formation region of the first transistor comprises polycrystalline silicon.

21. The manufacturing method of a display device according to claim 9,
wherein an inkjet method or a spin coating method is used as the wet process.

22. The manufacturing method of a display device according to claim 9, further comprising the step of:
forming a sacrificial layer below the first resist mask and the second resist mask.
